(19) United States
(12) Patent Application Publication
(10) Pub. No.: US 2026/0371510 A1
(43) Pub. Date: Nov. 19, 2026

(54) GUIDE FILM AND METHOD FOR MANUFACTURING ELECTRONIC DEVICE USING THE SAME

(71) Applicant: Samsung Display Co., Ltd., Yongin-si (KR)

(72) Inventors: Ki Chang LEE, Yongin-si (KR); Hyun Sang PARK, Yongin-si (KR); Ji Hoon SONG, Yongin-si (KR)

(21) Appl. No.: 19/563,689

(22) Filed: Mar. 11, 2026

(30) Foreign Application Priority Data
May 13, 2025 (KR) 10-2025-0062030

(51) Int. Cl. H05K 5/03

(52) U.S. Cl. CPC H05K 5/03

(57) ABSTRACT

A guide film includes a supporting face; and extension faces contacting portions of an edge of the supporting face, respectively. Between two adjacent extension faces, the edge of the supporting face includes a curve. The extension faces includes a first extension face extending in a first direction; a second extension face extending in a direction opposite to the first direction; a third extension face extending in a second direction intersecting the first direction; and a fourth extension face extending in a direction opposite to the second direction. The first extending face includes a first-1 portion extending from the supporting face in the first direction; and a first-2 portion extending from the first-1 portion in the first direction. In an area adjacent to an area where the first-1 portion contacts the first-2 portion, the first extension face defines a first-1 step shape and a first-2 step shape recessed toward each other.

This application claims priority to Korean Patent Application No. 10-2025-0062030, filed on May 13, 2025, and all the benefits accruing therefrom under 35 U.S.C. § 119, the content of which in its entirety is herein incorporated by reference.

### BACKGROUND

### 1. Field

The present disclosure relates to a guide film and a method for manufacturing an electronic device using the same.

### 2. Description of the Related Art

A display device (or an electronic device including the same) is a device for providing an image to a user. In recent years, display devices (or electronic devices including the same) having at least a portion of a display surface curved have been used to provide various functions and convenience to users.

The above-mentioned display device may include a display panel including a plurality of pixels and a window covering the display panel. The window may include a curved surface, and the display panel may have a portion of its shape deformed to correspond to the curved surface of the window.

### SUMMARY

The present disclosure provides a guide film suitable for a manufacturing process of a display device including a window having a curved surface, and a display panel attached below the window and having a portion of its shape deformed to correspond to the curved surface of the window.

The present disclosure provides an electronic device including a display device manufactured using the guide film.

A guide film according to embodiments of the present disclosure includes a supporting face; and extension faces contacting portions of an edge of the supporting face at positions spaced apart from each other, respectively. Between two adjacent extension faces among the extension faces, the edge of the supporting face includes a curve. The extension faces includes a first extension face extending from the supporting face in a first direction; a second extension face extending from the supporting face in a direction opposite to the first direction; a third extension face extending from the supporting face in a second direction intersecting the first direction; and a fourth extension face extending from the supporting face in a direction opposite to the second direction. The first extending face includes a first-1 portion extending from the supporting face in the first direction; and a first-2 portion extending from the first-1 portion in the first direction. In an area adjacent to an area where the first-1 portion and the first-2 portion are in contact, the first extension face defines a first-1 step shape and a first-2 step shape recessed toward each other.

In an embodiment, each of the first-1 step shape and the first-2 step shape may include a first stress absorption point where an edge of the first-1 portion and an edge of the first-2 portion meet to form an angle of 100 degrees or less.

In an embodiment, an average width in the second direction of the first-1 portion may be greater than an average width in the second direction of the first-2 portion.

In an embodiment, the first-1 step shape and the first-2 step shape may be symmetrical to each other with respect to a virtual line parallel to the first direction and crossing a center of the first extending face.

In an embodiment, each of the first-1 step shape and the first-2 step shape may be spaced apart from the supporting face.

In an embodiment, a shape of the first extension face and a shape of the second extension face may be symmetrical to each other with respect to a virtual line parallel to the second direction and crossing a center of the supporting face.

In an embodiment, a shape of the third extension face and a shape of the fourth extension face may be symmetrical to each other with respect to a virtual line parallel to the first direction and crossing a center of the supporting face.

In an embodiment, in an area adjacent to the supporting face, an edge of each of the extension faces may include a curve.

In an embodiment, a first length of a first side where the first extension face contacts the supporting face, a second length of a second side where the second extension face contacts the supporting face, a third length of a third side where the third extension face contacts the supporting face, and a fourth length of a fourth side where the fourth extension face contacts the supporting face may be defined, respectively. Each of the first length and the second length may be smaller than each of the third length and the fourth length.

A guide film according to embodiments of the present disclosure includes a supporting face; and extension faces contacting portions of an edge of the supporting face at positions spaced apart from each other, respectively. Between two adjacent extension faces among the extension faces, the edge of the supporting face includes a curve. The extension faces includes a first extension face extending from the supporting face in a first direction; a second extension face extending from the supporting face in a direction opposite to the first direction; a third extension face extending from the supporting face in a second direction intersecting the first direction; and a fourth extension face extending from the supporting face in a direction opposite to the second direction. The first extension face defines a first-1 through-pattern and a first-2 through-pattern therein, each penetrating the first extension face in a third direction perpendicular to both the first direction and the second direction.

In an embodiment, a shape of the first-1 through-pattern and a shape of the first-2 through-pattern may be symmetrical to each other with respect to a virtual line parallel to the first direction and crossing a center of the first extending face.

In an embodiment, each of the first-1 through-pattern and the first-2 through-pattern may have a rectangular shape with respective sides parallel to the first direction or the second direction.

In an embodiment, at least a portion of each of the first-1 through-pattern and the first-2 through-pattern may contact the supporting face.

In an embodiment, a shape of the first extension face and a shape of the second extension face may be symmetrical to each other with respect to a virtual line parallel to the second direction and crossing a center of the supporting face.

In an embodiment, a shape of the third extension face and a shape of the fourth extension face may be symmetrical to each other with respect to a virtual line parallel to the first direction and crossing a center of the supporting face.

In an embodiment, a first length of a first side where the first extension face contacts the supporting face, a second length of a second side where the second extension face contacts the supporting face, a third length of a third side where the third extension face contacts the supporting face, and a fourth length of a fourth side where the fourth extension face contacts the supporting face may be defined, respectively. Each of the first length and the second length may be smaller than each of the third length and the fourth length.

The present disclosure provides a method for manufacturing an electronic device. The electronic device includes a window including a curved surface; and a display panel attached below the window and having a shape partially deformed to correspond to the curved surface of the window. The method includes: deforming a shape of the display panel by applying tension to a guide film while the display panel is attached to the guide film. The guide film includes a supporting face; and extension faces contacting portions of an edge of the supporting face at positions spaced apart from each other, respectively. Between two adjacent extension faces among the extension faces, the edge of the supporting face includes a curve. The extension faces includes a first extension face extending from the supporting face in a first direction; a second extension face extending from the supporting face in a direction opposite to the first direction; a third extension face extending from the supporting face in a second direction intersecting the first direction; and a fourth extension face extending from the supporting face in a direction opposite to the second direction. The first extending face includes a first-1 portion extending from the supporting face in the first direction; and a first-2 portion extending from the first-1 portion in the first direction. In an area adjacent to an area where the first-1 portion and the first-2 portion are in contact, the first extension face defines a first-1 step shape and a first-2 step shape recessed toward each other.

The deforming of the shape of the display panel may include applying tension to each of the first extension face, the second extension face, the third extension face, and the fourth extension face.

The method for manufacturing the electronic device may further include attaching the window to the display panel having a deformed shape.

The display panel may include an attachment portion attached to the window; and a bending portion extending from the attachment portion, and in the deforming of the shape of the display panel, the attachment portion may be attached to the supporting face and be spaced apart from the extension faces, and the bending portion may overlap at least a portion of the first extending face.

An electronic device according to embodiments of the present disclosure may include a display device for displaying an image; and a processor for providing an image data signal to the display device. The display device may include a window including a curved surface; and a display panel attached below the window and having a shape partially deformed to correspond to the curved surface of the window. The display device may be manufactured by a manufacturing method. The manufacturing method may include deforming a shape of the display panel by applying tension to the guide film while the display panel is attached to the guide film. The guide film may include a supporting face to which the display panel is attached; and extension faces each contacting a portion of an edge of the supporting face at positions spaced apart from each other. Between two adjacent extension faces among the extension faces, the edge of the supporting face may include a curve. The extension faces may include a first extension face extending in a first direction; a second extension face extending in a direction opposite to the first direction; a third extension face extending in a second direction intersecting the first direction; and a fourth extension face extending in a direction opposite to the second direction. The first extending face may include a first-1 portion extending from the supporting face in the first direction; and a first-2 portion extending from the first-1 portion in the first direction. In an area adjacent to an area where the first-1 portion and the first-2 portion are in contact, the first extension face may define a first-1 step shape and a first-2 step shape recessed toward each other.

In an embodiment, the deforming the shape of the display panel may include applying tension to each of the first extension face, the second extension face, the third extension face, and the fourth extension face.

In an embodiment, the manufacturing method may further include attaching the window to the display panel having a deformed shape.

In an embodiment, the display panel may include an attachment portion attached to the window; and a bending portion extending from the attachment portion. In the deforming the shape of the display panel, the attachment portion may be attached to the supporting face and is spaced apart from the extension faces, and the bending portion may overlap at least a portion of the first extending face.

According to the present disclosure, a guide film may be provided to prevent excessive stress from being applied to a display panel when the display panel is attached to a window.

### BRIEF DESCRIPTION OF THE DRAWINGS

FIG. 1 is a perspective view to illustrate a display device according to an embodiment of the present disclosure.

FIG. 2 is an exploded view of the display device of FIG. 1.

FIG. 3 is a block diagram of an electronic device according to an embodiment of the present disclosure.

FIG. 4 is a schematic diagram of an electronic device according to various embodiments.

FIG. 5 is a plan view to illustrate a guide film according to an embodiment of the present disclosure.

FIG. 6 is a cross-sectional view cut along line I1-I2 of FIG. 5.

FIG. 7 is a cross-sectional view cut along line I3-I4 of FIG. 5.

FIGS. 8 to 10 are plan views to illustrate various variations of the first extension face included in the guide film of FIG. 5.

FIG. 11 is a plan view to illustrate a release film included in the guide film of FIG. 5.

FIGS. 12 to 17 are diagrams illustrating a manufacturing method for manufacturing the display device of FIG. 1 using the guide film of FIG. 5.

FIG. 18 is a drawing to illustrate the effect of a manufacturing method using the guide film of FIG. 5.

FIG. 19 is a plan view to illustrate a variant of the guide film of FIG. 5.

FIG. 20 is a plan view to illustrate another variant of the guide film of FIG. 5.

FIG. 21 is a plan view to illustrate a guide film according to another embodiment of the present disclosure.

FIG. 22 is a cross-sectional view cut along line I5-I6 of FIG. 21.

FIGS. 23 and 24 are plan views to illustrate different variations of the through-patterns of FIG. 21.

FIG. 25 is a plan view to illustrate a variant of the guide film of FIG. 21.

FIG. 26 is a plan view to illustrate another variant of the guide film of FIG. 21.

### DETAILED DESCRIPTION

Hereinafter, a preferred embodiment according to the present disclosure will be described in detail with reference to the accompanying drawings. It should be understood that in the following description, only those portions necessary to understand the operation according to the present disclosure will be described, and other portions will be omitted so as not to obscure the main points of the present disclosure. Furthermore, the present disclosure is not limited to the embodiments described herein and may be embodied in other forms. However, the embodiments described herein are merely exemplary and are provided in sufficient detail to enable those skilled in the art to readily implement the technical concept of the present disclosure.

Throughout the specification, when one part is said to be “connected” to another part, this includes not only “directly connected” but also “indirectly connected” with other elements in between. The terms used herein are intended to describe specific embodiments and are not intended to limit the present disclosure. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” Throughout the specification, when a part is said to “include” a component, it is meant to be inclusive of other components, not exclusive of other components, unless specifically noted to the contrary. “At least one of X, Y, and Z” and “at least one selected from an array including X, Y, and Z” can be interpreted as one X, one Y, one Z, or any combination of two or more of X, Y, and Z (e.g., XYZ, XY, YZ, ZX). As used herein, “and/or” includes any combination of one or more of those configurations.

As used herein, terms such as “first”, “second”, “first-1”, “first-2” and the like may be used to describe various components, but such components are not limited to such terms. These terms are used to distinguish one component from another. Thus, a first component may refer to a second component without departing from what is disclosed herein.

Spatially relative terms such as “on”, “above”, “under”, “above”, and the like may be used for purposes of description, and in so doing describe the relationship of one element or feature to another element(s) or feature(s) as shown in the drawings. Spatially relative terms are intended to include, in addition to the orientations depicted in the drawings, different orientations in use, operation, and/or manufacture. For example, when a device illustrated in the drawings is inverted, elements depicted as being located “below” other elements or features are oriented “above” other elements or features. Thus, in an embodiment, the term “underneath” may include both up and down directions. Furthermore, the device may be oriented in other directions (e.g., rotated 90 degrees or otherwise), and the spatially relative terms used herein are to be interpreted accordingly.

Various embodiments are described with reference to the drawings, which illustrate idealized embodiments. Accordingly, it is to be expected that the geometries may vary, for example, due to tolerances and/or manufacturing techniques. Accordingly, the embodiments disclosed herein should not be construed as limited to the specific geometries shown at, but should be construed to include changes in geometry that occur, for example, as a result of manufacturing. As such, the shapes illustrated in the drawings may not represent the actual shapes of the areas of the device, and the embodiments are not limited thereto.

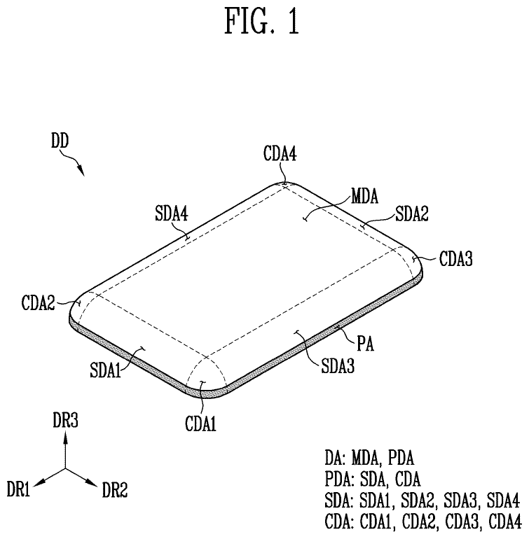

FIG. 1 is a perspective view to illustrate a display device according to an embodiment of the present disclosure.

Referring to FIG. 1, the display device DD may be a device for displaying an image. The display device DD may include a display area DA in which an image is displayed and a peripheral area PA surrounding the display area DA.

In an embodiment, the display area DA may include a main display area MDA and a peripheral display area PDA surrounding the main display area MDA.

In an embodiment, the display surface of the display device DD in the main display area MDA may be substantially flat. In FIG. 1, an embodiment is shown in which the main display area MDA has a rectangular shape in a plane defined by a first direction DR1 and a second direction DR2 intersecting (or perpendicular to) the first direction DR1. Here, a third direction DR3 may be a direction intersecting (or perpendicular to) the first direction DR1 and the second direction DR2, and may be in a direction opposite to the direction of action of gravity, according to embodiments. However, a shape of the main display area MDA is not limited thereto. For example, the main display area MDA may have a rounded rectangular shape including rounded vertices. For convenience of description, an embodiment in which the main display area MDA has a rectangular shape will be described as an example.

In an embodiment, an average width in the first direction DR1 of the display device DD may be greater than an average width in the second direction DR2 of the display device DD. In the aforementioned embodiments, in case the main display area MDA is rectangular in shape, a length of each of sides parallel to the first direction DR1 of the edge of the main display area MDA may be greater than a length of each of sides parallel to the second direction DR2. Each of the sides parallel to the first direction DR1 of the edge of the main display area MDA may be referred to as a “long side” and each of the sides parallel to the second direction DR2 may be referred to as a “short side”.

In an embodiment, a display surface of the display device DD in the peripheral display area PDA may include a curved surface. For example, the peripheral display area PDA may include a side display area SDA and a corner display area CDA, and each of the side display area SDA and the corner display area CDA may include a curved surface.

The side display area SDA may include a first side display area SDA1, a second side display area SDA2, a third side display area SDA3, and a fourth side display area SDA4.

The first side display area SDA1 may be adjacent to the main display area MDA in the first direction DR1. The second side display area SDA2 may be adjacent to the main display area MDA in a direction opposite to the first direction DR1. The third side display area SDA3 may be adjacent to the main display area MDA in the second direction DR2. A fourth side display area SDA4 may be adjacent to the main display area MDA in a direction opposite to the second direction DR2.

The corner display area CDA may include a first corner display area CDA1, a second corner display area CDA2, a third corner display area CDA3, and a fourth corner display area CDA4.

The first corner display area CDA1 may contact (or abut) at least a portion of the first side display area SDA1 and at least a portion of the third side display area SDA3 between the first side display area SDA1 and the third side display area SDA3, respectively.

The second corner display area CDA2 may contact at least a portion of the first side display area SDA1 and at least a portion of the fourth side display area SDA4 between the first side display area SDA1 and the fourth side display area SDA4, respectively.

The third corner display area CDA3 may contact at least a portion of the second side display area SDA2 and at least a portion of the third side display area SDA3 between the second side display area SDA2 and the third side display area SDA3, respectively.

The fourth corner display area CDA4 may contact at least a portion of the second side display area SDA2 and at least a portion of the fourth side display area SDA4 between the second side display area SDA2 and the fourth side display area SDA4, respectively.

In an embodiment, the peripheral area PA may surround the display area DA. However, the present disclosure is not limited thereto. For example, a portion of the peripheral area PA or all of the peripheral area PA may be omitted.

In the embodiments described above, the display device DD may have a flat-dome shape in which a top surface (e.g., a display surface corresponding to the main display area MDA) is substantially flat. When the display device DD is viewed in a direction opposite to the third direction DR3, the display device DD may have a rounded rectangular shape including rounded vertices.

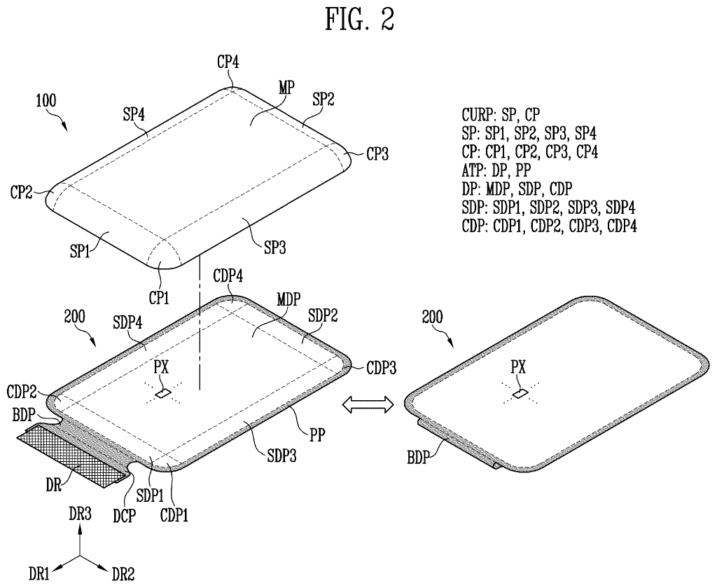

FIG. 2 is an exploded view of the display device of FIG. 1.

Referring to FIG. 2, the display device DD (see FIG. 1) may include a window 100 and a display panel 200.

The window 100 may include a main portion MP and a curved portion CURP surrounding the main portion MP.

The main portion MP may correspond to the main display area MDA (see FIG. 1). The main portion MP may have a shape corresponding to the main display area MDA (see FIG. 1). For example, the main portion MP may be substantially flat. For example, the main portion MP may have a rectangular shape in a plane defined by the first direction DR1 and the second direction DR2. For example, a length of each of sides of an edge of the main portion MP parallel to the first direction DR1 may be greater than a length of each of sides of the edge parallel to the second direction DR2.

The curved portion CURP may correspond to a peripheral display area PDA (see FIG. 1) and a peripheral area PA (see FIG. 1). The curved portion CURP may include a side portion SP and a corner portion CP, and each of a side portion SP and a corner portion CP may include a curved surface.

The side portion SP may include a first side portion SP1, a second side portion SP2, a third side portion SP3, and a fourth side portion SP4.

The first side portion SP1 may be adjacent to the main portion MP in the first direction DR1. The first side portion SP1 may correspond to the first side display area SDA1 (see FIG. 1) and a portion of the peripheral area PA (see FIG. 1) adjacent thereto.

The second side portion SP2 may be adjacent to the main portion MP in the direction opposite to the first direction DR1. The second side portion SP2 may correspond to the second side display area SDA2 (see FIG. 1), and a portion of the peripheral area PA (see FIG. 1) adjacent thereto.

The third side portion SP3 may be adjacent to the main portion MP in the second direction DR2. The third side portion SP3 may correspond to the third side display area SDA3 (see FIG. 1), and a portion of the peripheral area PA (see FIG. 1) adjacent thereto.

The fourth side portion SP4 may be adjacent to the main portion MP in the direction opposite to the second direction DR2. The fourth side portion SP4 may correspond to the fourth side display area SDA4 (see FIG. 1) and a portion of peripheral area PA (see FIG. 1) adjacent thereto.

The corner portion CP may include a first corner portion CP1, a second corner portion CP2, a third corner portion CP3, and a fourth corner portion CP4.

The first corner portion CP1 may contact at least a portion of the first side portion SP1 and at least a portion of the third side portion SP3, respectively, between the first side portion SP1 and the third side portion SP3. The first corner portion CP1 may correspond to the first corner display area CDA1 (see FIG. 1) and a portion of the peripheral area PA (see FIG. 1) adjacent thereto.

The second corner portion CP2 may contact at least a portion of the first side portion SP1 and at least a portion of the fourth side portion SP4 between the first side portion SP1 and the fourth side portion SP4, respectively. The second corner portion CP2 may correspond to the second corner display area CDA2 (see FIG. 1) and a portion of the peripheral area PA (see FIG. 1) adjacent thereto.

The third corner portion CP3 may contact at least a portion of the second side portion SP2 and at least a portion of the third side portion SP3 between the second side portion SP2 and the third side portion SP3, respectively. The third corner portion CP3 may correspond to the third corner display area CDA3 (see FIG. 1), and a portion of the peripheral area PA (see FIG. 1) adjacent thereto.

The fourth corner portion CP4 may contact at least a portion of the second side portion SP2 and at least a portion of the fourth side portion SP4 between the second side portion SP2 and the fourth side portion SP4, respectively. The fourth corner portion CP4 may correspond to the fourth corner display area CDA4 (see FIG. 1), and a portion of the peripheral area PA (see FIG. 1) adjacent thereto.

The display panel 200 may include an attachment portion ATP, a bending portion BDP, a connection portion DCP, and a driving member DR. The display panel 200 may be flexible. As such, the display panel 200 may be deformed by external forces. For ease of description, the display panel 200 will be described below with reference to the display panel 200 having a shape substantially parallel to a plane defined by the first direction DR1 and the second direction DR2. However, the present disclosure is not limited thereto, and the shape of the display panel 200 may be deformed by external forces as described above.

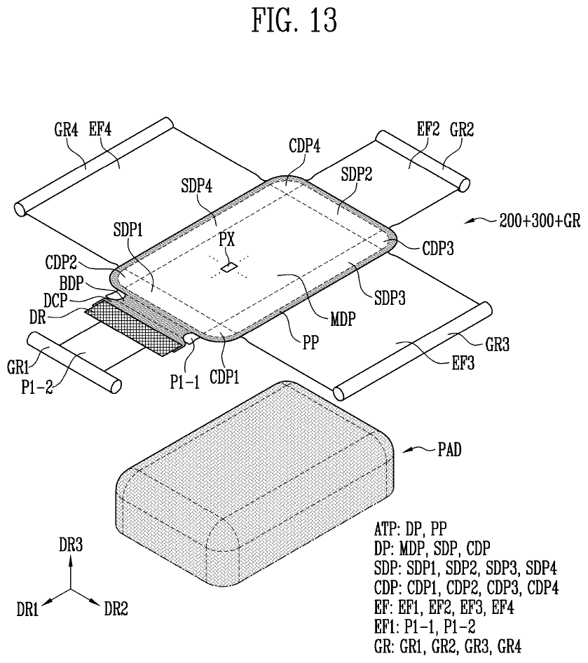

The attachment portion ATP may be a portion that is attached to the window 100. When the attachment portion ATP is attached to the window 100, a shape of the attachment portion ATP may be deformed to correspond to a shape of the curved surface of the window 100. This will be discussed further with reference to FIGS. 13 to 16.

The attachment portion ATP may include a display portion DP and a peripheral portion PP.

The display portion DP may include a plurality of pixels PX. Each of the plurality of pixels PX may emit light. The light emitted from the plurality of pixels PX may be combined to display an image. In an embodiment, the plurality of pixels PX may be arranged in a matrix along the first direction DR1 and the second direction DR2. However, the present disclosure is not limited thereto. For example, the plurality of pixels PX may be arranged in a zigzag pattern along the first direction DR1 and the second direction DR2.

In an embodiment, the display portion DP may include a main display portion MDP, a side display portion SDP, and a corner display portion CDP.

The main display portion MDP may be attached below the main portion MP. The main display portion MDP may correspond to the main display area MDA (see FIG. 1). An image may be displayed in the main display area MDA (see FIG. 1) by a plurality of pixels PX in the main display portion MDP.

The side display portion SDP may be attached below the side portion SP. In this case, a shape of the side display portion SDP may be deformed to correspond to a shape of the side portion SP. The side display portion SDP may correspond to the side display area SDA (see FIG. 1). An image may be displayed in the side display area SDA (see FIG. 1) by a plurality of pixels PX in the side display portion SDP.

The side display portion SDP may include a first side display portion SDP1, a second side display portion SDP2, a third side display portion SDP3, and a fourth side display portion SDP4.

The first side display portion SDP1 may be adjacent to the main display portion MDP in the first direction DR1. The first side display portion SDP1 may be attached below the first side portion SP1, in which case a shape of the first side display portion SDP1 may be deformed (or modified) to correspond to a shape of the first side portion SP1. The first side display portion SDP1 may correspond to the first side display area SDA1 (see FIG. 1).

The second side display portion SDP2 may be adjacent to the main display portion MDP in the direction opposite to the first direction DR1. The second side display portion SDP2 may be attached below the second side portion SP2, in which case a shape of the second side display portion SDP2 may be deformed to correspond to a shape of the second side portion SP2. The second side display portion SDP2 may correspond to the second side display area SDA2 (see FIG. 1).

The third side display portion SDP3 may be adjacent to the main display portion MDP in the second direction DR2. The third side display portion SDP3 may be attached below the third side portion SP3, in which case a shape of the third side display portion SDP3 may be deformed to correspond to a shape of the third side portion SP3. The third side display portion SDP3 may correspond to the third side display area SDA3 (see FIG. 1).

The fourth side display portion SDP4 may be adjacent to the main display portion MDP in the direction opposite to the second direction DR2. The fourth side display portion SDP4 may be attached below the fourth side portion SP4, in which case a shape of the fourth side display portion SDP4 may be deformed to correspond to a shape of the fourth side portion SP4. The fourth side display portion SDP4 may correspond to the fourth side display area SDA4 (see FIG. 1).

The corner display portion CDP may be attached below the corner portion CP. In this case, a shape of the corner display portion CDP may be deformed to correspond to a shape of the corner portion CP. The corner display portion CDP may correspond to the corner display area CDA (see FIG. 1). An image may be displayed in the corner display area CDA (see FIG. 1) by a plurality of pixels PX in the corner display portion CDP.

The corner display portion CDP may include a first corner display portion CDP1, a second corner display portion CDP2, a third corner display portion CDP3, and a fourth corner display portion CDP4.

The first corner display portion CDP1 may contact at least a portion of the first side display portion SDP1 and at least a portion of the third side display portion SDP3, respectively, between the first side display portion SDP1 and the third side display portion SDP3. The first corner display portion CDP1 may be attached below the first corner portion CP1, in which case a shape of the first corner display portion CDP1 may be deformed to correspond to a shape of the first corner portion CP1. The first corner display portion CDP1 may correspond to the first corner display area CDA1 (see FIG. 1).

The second corner display portion CDP2 may contact at least a portion of the first side display portion SDP1 and at least a portion of the fourth side display portion SDP4 between the first side display portion SDP1 and the fourth side display portion SDP4, respectively. The second corner display portion CDP2 may be attached below the second corner portion CP2, in which case a shape of the second corner display portion CDP2 may be deformed to correspond to a shape of the second corner portion CP2. The second corner display portion CDP2 may correspond to the second corner display area CDA2 (see FIG. 1).

The third corner display portion CDP3 may contact at least a portion of the second side display portion SDP2 and at least a portion of the third side display portion SDP3, respectively, between the second side display portion SDP2 and the third side display portion SDP3. The third corner display portion CDP3 may be attached below the third corner portion CP3, in which case a shape of the third corner display portion CDP3 may be modified to correspond to a shape of the third corner portion CP3. The third corner display portion CDP3 may correspond to the third corner display area CDA3 (see FIG. 1).

The fourth corner display portion CDP4 may contact at least a portion of the second side display portion SDP2 and at least a portion of the fourth side display portion SDP4, respectively, between the second side display portion SDP2 and the fourth side display portion SDP4. The fourth corner display portion CDP4 may be attached below the fourth corner display portion CP4, in which case a shape of the fourth corner display portion CDP4 may be modified to correspond to a shape of the fourth corner display portion CP4. The fourth corner display portion CDP4 may correspond to the fourth corner display area CDA4 (see FIG. 1).

The peripheral portion PP may include a driving circuit for providing electrical signals to the plurality of pixels PX. The peripheral portion PP may surround at least a portion of the display portion DP. In an embodiment, as shown in FIG. 2, the peripheral portion PP may entirely surround the display portion DP. However, the present disclosure is not limited thereto. For example, the peripheral portion PP may be omitted, in which case the driving circuit may be disposed on a back surface of the display panel 200.

The peripheral portion PP may be attached below the curved portion CURP. In this case, a shape of the peripheral portion PP may be deformed to correspond to a shape of the curved portion CURP. The peripheral portion PP may correspond to the peripheral area PA (see FIG. 1). However, in case the peripheral portion PP is omitted as described above, the peripheral area PA (see FIG. 1) may also be omitted, and the entire front surface of the display device DD (see FIG. 1) may be provided as a display surface.

The connection portion DCP may be spaced apart from the attachment portion ATP in the first direction DR1. The driving member DR may be disposed on the connection portion DCP. The driving member DR may serve to generate electrical signals required to drive a plurality of pixels PX and/or to transmit the electrical signals required to drive the plurality of pixels PX. The connection portion DCP may include a signal transmission member (e.g., electrodes and/or wiring) connected to the driving member DR. The connection portion DCP may serve to transmit electrical signals provided by the driving member DR. In an embodiment, the driving member DR may be mounted on the connection portion DCP in the form of a chip-on-film.

The bending portion BDP may be disposed between the connection portion DCP and the attachment portion ATP. The bending portion BDP may include a signal transmission wire connected to the signal transmission member included in the connection portion DCP. The signal transmission wiring may be connected to the driving circuit disposed in the plurality of pixels PX and/or in the peripheral portion PP.

In an embodiment, the bending portion BDP may be bent to have a curvature. For example, referring to FIG. 2, a display panel 200 with the bending portion BDP unbent is shown on the left, and a display panel 200 with the bending portion BDP bent is shown on the right. As the bending portion BDP is bent, the connection portion DCP and the driving member DR may be disposed on a back surface of the display panel 200.

The display device described above may be applied to a variety of electronic devices. An electronic device according to an embodiment includes the display device described above, and may further include modules or devices having other additional functions in addition to the display device.

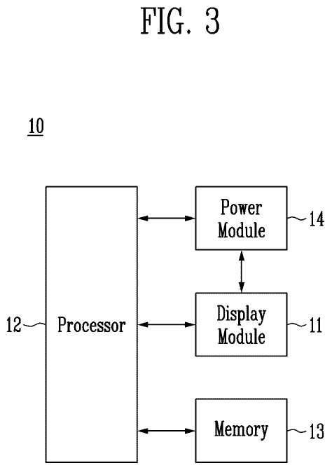

FIG. 3 is a block diagram of an electronic device according to an embodiment of the present disclosure.

Referring to FIG. 3, an electronic device 10 according to an embodiment may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller.

The memory 13 may store data information required for operation of the processor 12 or the display module 11. When the processor 12 executes an application stored in the memory 13, image data signals and/or input control signals may be delivered to the display module 11, and the display module 11 may process the received signals to output image information via a display surface.

The power module 14 may include a power supply module, such as a power adapter or a battery device, and a power conversion module that converts the power supplied by the power supply module to generate the power required for operation of the electronic device 10.

At least one of each of the aforementioned configurations of the electronic device 10 may be included within the display device according to the aforementioned embodiments. Furthermore, some of individual modules that are functionally included within one module may be included within the display device and others may be provided separately from the display device. For example, the display device may include the display module 11, while the processor 12, the memory 13, and the power module 14 may be provided in the form of other devices within the electronic device 10 other than the display device.

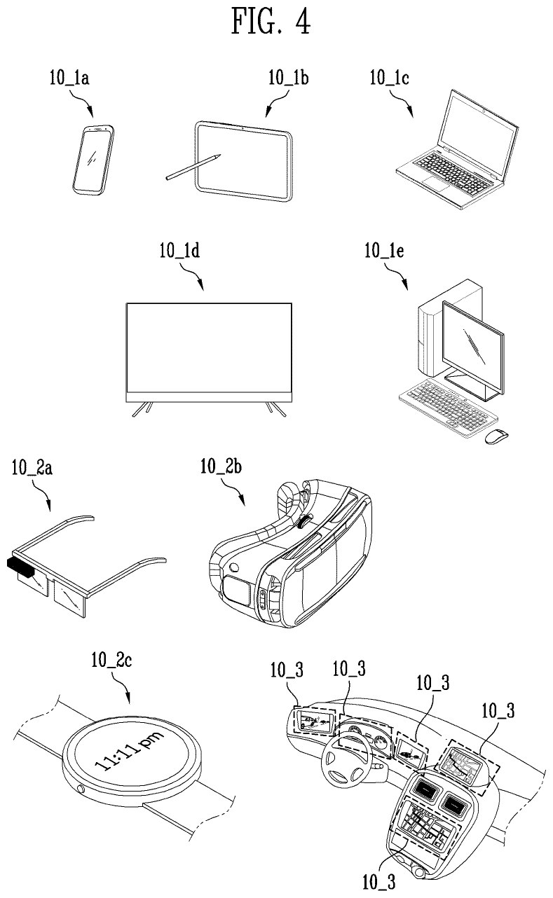

FIG. 4 is a schematic diagram of an electronic device according to various embodiments.

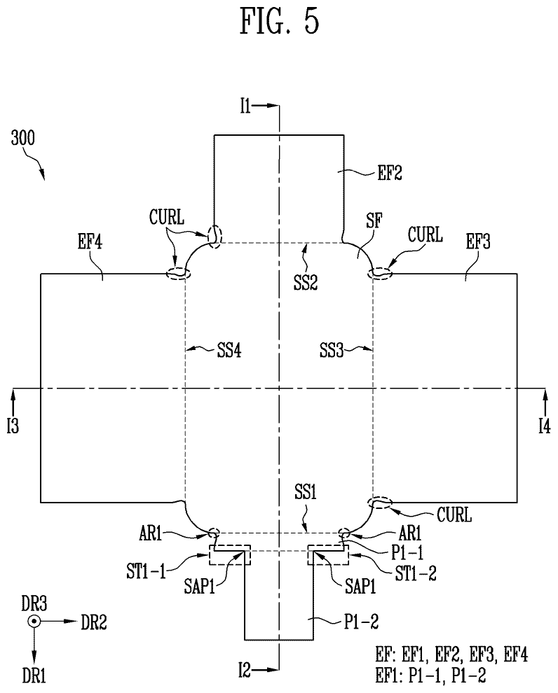

Referring to FIG. 4, various electronic devices with display devices according to embodiments include an electronic device for displaying an image, such as a smartphone 10_1a, a tablet PC 10_1b, a laptop 10_1c, a television 10_1d, a desk monitor 10_1e, as well as a wearable electronic device including a display module such as a smart glasses 10_2a, a head-mounted display 10_2b, a smart watch 10_2c, and the like, an automotive electronic device 10_3 including a display module such as a center information display (CID), a room mirror display, and the like disposed on an instrument panel, a center fascia, or a dashboard of an automobile, and the like. Hereinafter, with reference to FIGS. 5 to 11, a guide film according to an embodiment of the present disclosure will be described. The guide film may be used to manufacture the display device DD described with reference to FIGS. 1 and 2. The display device DD may be applied to the electronic device 10 described with reference to FIGS. 3 and 4.

FIG. 5 is a plan view to illustrate a guide film according to an embodiment of the present disclosure. As used herein, the “plan view” of the guide film is a view in a thickness direction (i.e., third direction DR3) of the supporting face of the guide film.

Referring to FIG. 5, the guide film 300 may have flexibility. In an embodiment, the guide film 300 may have rigid properties relative to the display panel 200, but the present disclosure is not limited thereto. As the guide film 300 is flexible, a shape of the guide film 300 may be deformed by external forces. Hereinafter, for ease of description, the guide film 300 will be described based on a state of the guide film 300 having a shape substantially parallel to a plane defined by the first direction DR1 and the second direction DR2. However, the present disclosure is not limited thereto, and the shape of the guide film 300 may be deformed by external forces, as described above.

The guide film 300 may include a supporting face SF and extension faces EF.

The supporting face SF may be attached to a back surface of the display panel 200 (see FIG. 2). More specifically, the supporting face SF may be attached to a back surface of the attachment portion ATP (see FIG. 2). The supporting face SF may serve to support the attachment portion ATP (see FIG. 2).

The supporting face SF may have a shape corresponding to the shape of the attachment portion ATP (see FIG. 2). In an embodiment, the supporting face SF may have a rounded rectangular shape including rounded vertices. In an embodiment, an average width in the first direction DR1 of the supporting face SF may be greater than an average width in the second direction DR2 of the supporting face SF.

The extension faces EF may each contact a portion of an edge of the supporting face SF (e.g., first to fourth sides SS1, SS2, SS3, and SS4) at positions spaced apart from each other. The extension faces EF may be spaced apart from each other. In an embodiment, the shape of the supporting face SF may be deformed by applying a tension in a certain direction to each of the extension faces EF. In this case, if the attachment portion ATP (see FIG. 2) attached to the supporting face SF, the shape of the attachment portion ATP (see FIG. 2) attached to the supporting face SF may also be deformed when a certain directional tension is applied to each of the extension faces EF. As such, the guide film 300 may be used to deform a shape of the display panel 200 (see FIG. 2) without directly applying tension to the display panel 200 (see FIG. 2).

In an embodiment, the extension faces EF may include a first extension face EF1, a second extension face EF2, a third extension face EF3, and a fourth extension face EF4.

The first extension face EF1 may be adjacent to the supporting face SF in the first direction DR1. The first extension face EF1 may extend in the first direction DR1. The second extension face EF2 may be adjacent to the supporting face SF in the direction opposite to the first direction DR1. The second extension face EF2 may extend in the direction opposite to the first direction DR1. The third extension face EF3 may be adjacent to the supporting face SF in the second direction DR2. The third extension face EF3 may extend in the second direction DR2. The fourth extension face EF4 may be adjacent to the supporting face SF in the direction opposite to the second direction DR2. The fourth extension face EF4 may extend in the direction opposite to the second direction DR2.

In an embodiment, between two extension faces EF among the extension faces EF that are adjacent to each other, an edge of the supporting face SF may include a curve. For example, between the first extension face EF1 and the third extension face EF3, between the first extension face EF1 and the fourth extension face EF4, between the second extension face EF2 and the third extension face EF3, and between the second extension face EF2 and the fourth extension face EF4, the edge of the supporting face SF may include a curve.

In an embodiment, the first extension face EF1 may include a first-1 portion P1-1 and a first-2 portion P1-2. The first-1 portion P1-1 may be a portion adjacent to the supporting face SF in the first direction DR1. The first-1 portion P1-1 may extend from the supporting face SF in the first direction DR1. The first-2 portion P1-2 may be a portion adjacent to the first-1 portion P1-1 in the first direction DR1. The first-2 portion P1-2 may extend in the first direction DR1 from the first-1 portion P1-1. The first-2 portion P1-2 may be spaced apart from the supporting face SF, and the first-1 portion P1-1 may be disposed between the first-2 portion P1-2 and the supporting face SF.

In an embodiment, in an area adjacent to an area where the first-1 portion P1-1 and the first-2 portion P1-2 are in contact, the first extension face EF1 may define a first-1 step shape ST1-1 and a first-2 step shape ST1-2 that are embedded in a direction facing each other. Each of the first-1 step shape ST1-1 and the first-2 step shape ST1-2 may be a step shape formed between the first-1 portion P1-1 and the first-2 portion P1-2.

The first-1 step shape ST1-1 and the first-2 step shape ST1-2 may serve to prevent stresses caused by tension applied to the first extension face EF1 from being concentrated in a first adjacent area AR1 adjacent to a portion of the supporting face SF contacting the first extension face EF1. In other words, the first-1 step shape ST1-1 and the first-2 step shape ST1-2 may serve to absorb stresses caused by tension applied to the first extension face EF1.

When the attachment portion ATP (see FIG. 2) is attached to the supporting face SF, the first extension face EF1 may overlap the bending portion BDP (see FIG. 2), the connection portion DCP (see FIG. 2), and the driving member DR (see FIG. 2). A portion of the attachment portion ATP (see FIG. 2) adjacent to the bending portion BDP (see FIG. 2) may be particularly vulnerable to damage due to stress concentration. To deform the shape of the attachment portion ATP (see FIG. 2) to correspond to the shape of the curved surface of the window 100 (see FIG. 2), a tension may be applied to each of the extension faces EF, including the first extension face EF1. In this case, as the first-1 step shape ST1-1 and the first-2 step shape ST1-2 absorb the stresses caused by the tension, stresses may be effectively prevented from being concentrated in the portion of the attachment portion ATP (see FIG. 2) adjacent to the bending portion BDP (see FIG. 2).

In an embodiment, each of the first-1 step shape ST1-1 and the first-2 step shape ST1-2 may include a first stress absorption point SAP1, which is a point where an edge of the first-1-1 portion P1-1 and an edge of the first-1-2 portion P1-2 meet to form an angle below a reference angle. The reference angle may be, for example, about 150 degrees or less, about 140 degrees or less, about 130 degrees or less, about 120 degrees or less, about 110 degrees or less, about 100 degrees or less, about 90 degrees or less, about 80 degrees or less, about 70 degrees or less, or about 60 degrees or less. When the reference angle is set as described above, stresses may be effectively concentrated at the first stress absorption point SAP1.

The first stress absorption point SAP1 may be a point at which stresses caused by tension applied to the first extension face EF1 are concentrated. As such, each of the first-1 step shape ST1-1 and the first-2 step shape ST1-2 may include the first stress absorption point SAP1 so that the first-1 step shape ST1-1 and the first-2 step shape ST1-2 may more effectively absorb the stresses caused by the tension.

The first portion P1-1 and the second portion P1-2 may have various shapes capable of defining the first-1 step shape ST1-1 and the first-2 step shape ST1-2. In an embodiment, an average width in the second direction DR2 of the first-1 portion P1-1 may be greater than an average width in the second direction DR2 of the first-2 portion P1-2. In this case, in an area adjacent to an area where the first-1 portion P1-1 and the second-2 portion P1-2 are in contact, the first-1 step shape ST1-1 and the first-2 step shape ST1-2 may be defined by a difference between a width in the second direction DR2 of the first-1 portion P1-1 and a width in the second direction DR2 of the second-2 portion P1-2.

In an embodiment, the first-1 step shape ST1-1 and the first-2 step shape ST1-2 may be symmetrical to each other. For example, line I1-I2 shown in FIG. 5 may be a line extending in the first direction DR1 through a center of the supporting face SF. The first-1 step shape ST1-1 and the first-2 step shape ST1-2 may be symmetrical to each other with respect to the line I1-I2. In this case, the stresses caused by the tension applied to the first extension face EF1 may be prevented from being biased in the second direction DR2 or in the direction opposite to the second direction DR2. That is, the stresses caused by the tension may be evenly distributed and the maximum intensity of these stresses may be reduced.

In an embodiment, each of the first-1 step shape ST1-1 and the first-2 step shape ST1-2 may be spaced apart from the supporting face SF. Accordingly, stresses absorbed by the first-1 step shape ST1-1 and the first-2 step shape ST1-2 may be prevented from being transmitted to the supporting face SF (or to the attachment portion ATP attached to the supporting face SF (see FIG. 2)).

In an embodiment, a shape of the third extension face EF3 and a shape of the fourth extension face EF4 may be symmetrical to each other. For example, the shape of the third extension face EF3 and the shape of the fourth extension face EF4 may be symmetrical to each other with respect to the line I1-I2. In this case, tension applied to the third extension face EF3 and tension applied to the fourth extension face EF4 may be balanced, thereby preventing stresses from being concentrated in a particular area of the supporting face SF (or the attachment portion ATP attached to the supporting face SF (see FIG. 2)).

In an embodiment, in an area adjacent to the supporting face SF, an edge of each of the extension faces EF may include a curve. For example, in an area adjacent to the supporting face SF, the edge of the third extension face EF3 may include a curve CURL. Similarly, in the area adjacent to the supporting face SF, the edge of the first extension face EF1 (or the first-1 portion P1-1), the edge of the second extension face EF2, and the edge of the fourth extension face EF4 may include a curve CURL. In this case, the stresses caused by the tension applied to the extension faces EF may be effectively prevented from being concentrated in adjacent areas (e.g., the first adjacent area AR1) adjacent portions of the supporting face SF contacting the extension faces EF.

In an embodiment, a first length of a first side SS1 where the first extension face EF1 and the supporting face SF are in contact, a second length of a second side SS2 where the second extension face EF2 and the supporting face SF are in contact, a third length of a third side SS3 where the third extension face EF3 and the supporting face SF are in contact, and a fourth length of a fourth side SS4 where the fourth extension face EF4 and the supporting face SF are in contact may be defined, respectively. Each of the first length and the second length may be smaller than each of the third length and the fourth length.

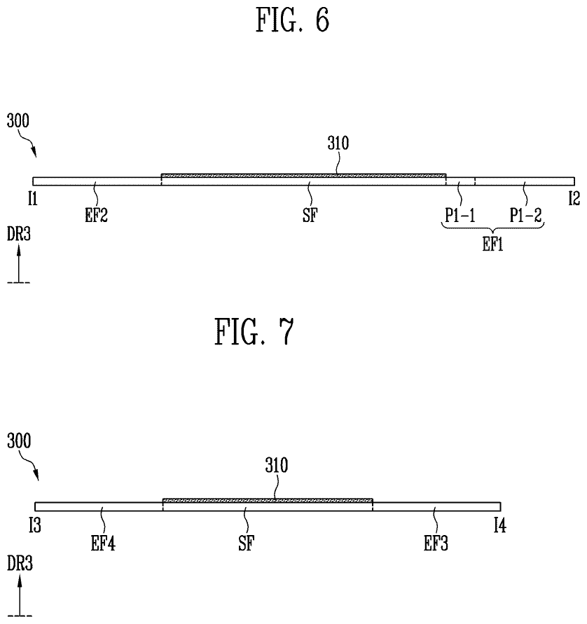

FIG. 6 is a cross-sectional view cut along line I1-I2 of FIG. 5. FIG. 7 is a cross-sectional view cut along line I3-I4 of FIG. 5.

Referring to FIGS. 6 and 7, in an embodiment, the supporting face SF, the first extension face EF1, the second extension face EF2, the third extension face EF3, and the fourth extension face EF4 may be different portions compartmentalized within the same film layer. That is, the supporting face SF, the first extension face EF1, the second extension face EF2, the third extension face EF3, and the fourth extension face EF4 may be integrally formed.

In an embodiment, the guide film 300 may further include an adhesive layer 310 disposed entirely over the supporting face SF. The adhesive layer 310 may serve to secure the attachment portion ATP (see FIG. 2) to the supporting face SF when the attachment portion ATP (see FIG. 2) is disposed on the supporting face SF.

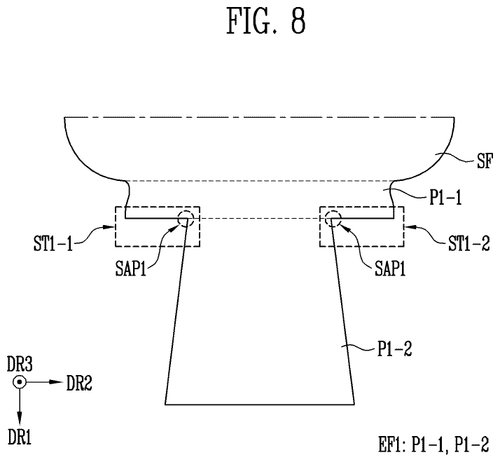

FIGS. 8 to 10 are plan views to illustrate various variations of the first extension face included in the guide film of FIG. 5.

Referring to FIG. 8, the first-2 portion P1-2 may have a shape in which a width in the second direction DR2 increases along the first direction DR1. In this case, the first-1 step shape ST1-1 and the first-2 step shape ST1-2 may be defined, as shown in FIG. 8. On the other hand, compared to the embodiment of FIG. 5 in which the first-2 portion P1-2 has a shape having a constant width in the second direction DR2 along the first direction DR1, in the embodiment shown in FIG. 8, the reference angle at which the edge of the first-1 portion P1-1 and the edge of the first-2 portion P1-2 meet at the first stress absorption point SAP1 may be smaller.

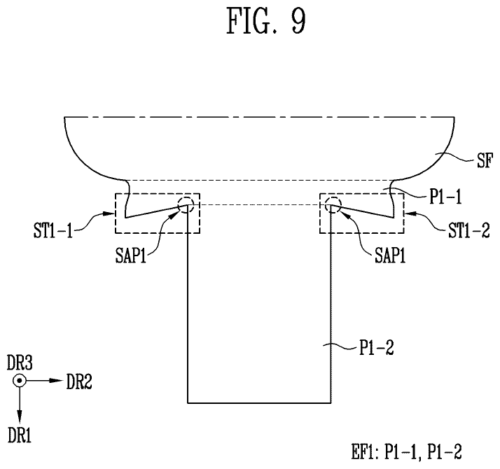

Referring to FIG. 9, a portion of the edge of the first-1 portion P1-1 that is adjacent to the first-2 portion P1-2 may have a shape of an oblique line extending in a direction intersecting the second direction DR2. In this case, the first-1 step shape ST1-1 and the first-2 step shape ST1-2 may be defined, as shown in FIG. 9. On the other hand, compared to the embodiment of FIG. 5, in the embodiment shown in FIG. 9, the reference angle at which the edge of the first-1 portion P1-1 and the edge of the first-2 portion P1-2 meet at the first stress absorption point SAP1 may be smaller.

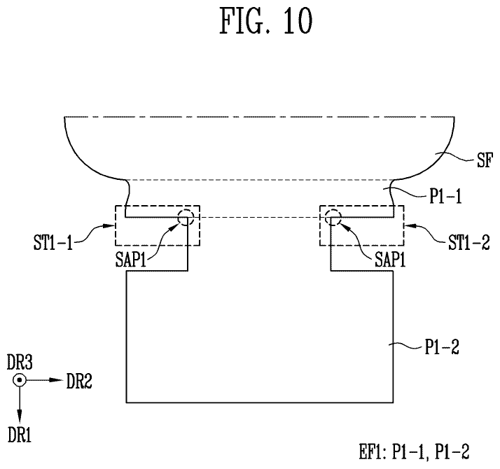

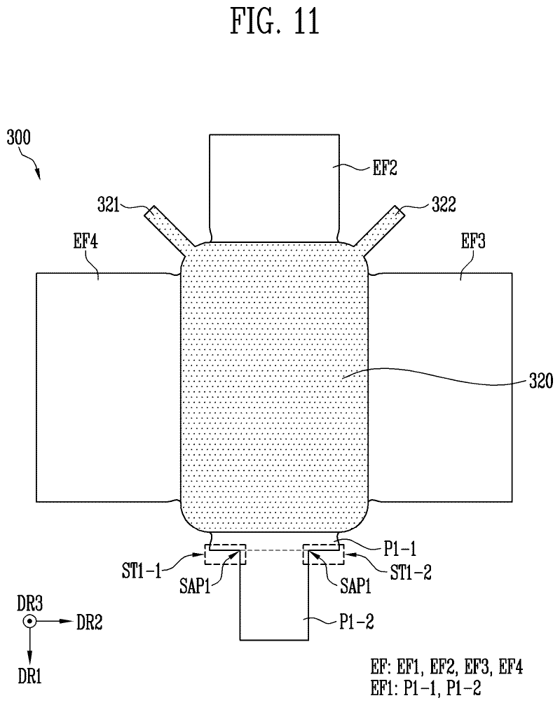

Referring to FIG. 10, the first-2 portion P1-2 may have a first width in the second direction DR2 in an area adjacent to the first-1 portion P1-1 and a second width in the second direction DR2 in an area spaced apart from the first-1 portion P1-1, and the second width may be larger than the first width. In this case, the first-1 step shape ST1-1 and the first-2 step shape ST1-2 may be defined, as shown in FIG. 10.

As described with reference to FIGS. 8 to 10, the first-1 portion P1-1 and the first-2 portion P1-2 may have various shapes capable of defining the first-1 step shape ST1-1 and the first-2 step shape ST1-2.

FIG. 11 is a plan view to illustrate a release film included in the guide film of FIG. 5.

Referring to FIG. 11, the guide film 300 may further include a release film 320. The release film 320 may be attached to the supporting face SF (see FIG. 5). For example, the release film 320 may be attached to the supporting face SF (see FIG. 5) by the adhesive layer 310 (see FIGS. 6 and 7). The release film 320 may serve to prevent impurities from coming into contact with the adhesive layer 310 (see FIGS. 6 and 7) prior to the guide film 300 being attached to the display panel 200 (see FIG. 2). In an embodiment, the release film 320 may be removed in order to attach the display panel 200 (see FIG. 2) to the guide film 300. For example, the release film 320 may include a first protrusion 321 and a second protrusion 322 that are non-overlapping with the extension faces EF, and the first protrusion 321 and the second protrusion 322 may be used to separate the release film 320 from the guide film 300.

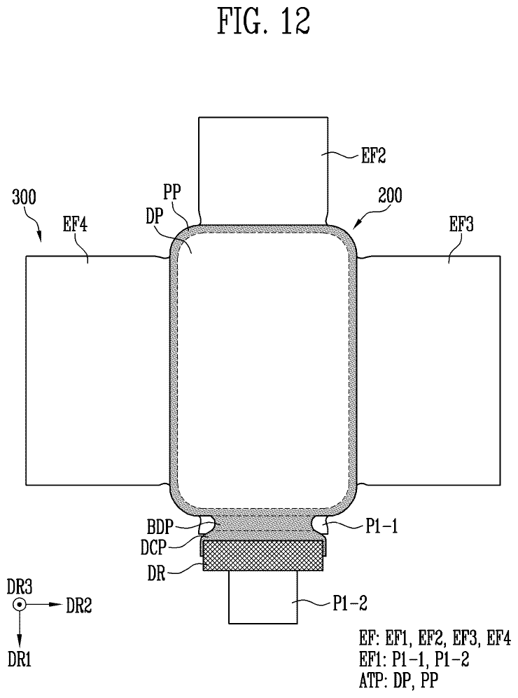

FIGS. 12 to 17 are diagrams illustrating a manufacturing method for manufacturing the display device of FIG. 1 using the guide film of FIG. 5.

As previously described, the display device DD (see FIG. 1) may include the window 100 (see FIG. 2) that includes a curved surface, and the display panel 200 (see FIG. 2) that is attached below the window 100 (see FIG. 2) and has a shape partially deformed to correspond to the curved surface of the window 100 (see FIG. 2).

In this case, the manufacturing method for the display device DD (see FIG. 1) may include deforming the shape of the display panel 200 (see FIG. 2) by applying tension to the guide film 300 (see FIG. 5) while the display panel 200 (see FIG. 2) is attached to the guide film 300 (see FIG. 5).

In this way, the guide film 300 (see FIG. 5) may be utilized to deform the shape of the display panel 200 (see FIG. 2) into a shape that substantially corresponds to the curved surface of the window 100 (see FIG. 2). Thus, the coupling of the window 100 (see FIG. 2) and the display panel 200 (see FIG. 2) may be facilitated.

Further, by applying tension to the guide film 300 (see FIG. 5) rather than directly to the display panel 200 (see FIG. 2), the display panel 200 (see FIG. 2) may be prevented from breaking under tension.

Hereinafter, a manufacturing method for the display device DD (see FIG. 1) using the guide film 300 (see FIG. 5) will be described in detail with reference to FIGS. 12 to 17. Descriptions that are redundant to those described with reference to FIGS. 1 to 11 may be omitted.

FIG. 12 is a plan view illustrating a display panel 200 attached to a guide film 300.

Referring to FIG. 12, the manufacturing method for the display device DD (see FIG. 1) may include attaching the display panel 200 to the guide film 300.

In this step, an attachment portion ATP of the display panel 200 may be attached to the supporting face SF (see FIG. 5) of the guide film 300. For example, the attachment portion ATP may be attached to the supporting face SF (see FIG. 5) via the adhesive layer 310 (see FIGS. 6 and 7).

In an embodiment, a shape of the attachment portion ATP may be substantially the same as a shape of the supporting face SF. However, the present disclosure is not limited thereto. For example, the shape of the supporting face SF may be larger or smaller than the shape of the attachment portion ATP. For example, a portion of the supporting face SF that overlaps with the corner display portion CDP (see FIG. 2) may be removed.

In this step, each of the bending portion BDP, the connection portion DCP, and the driving member DR may overlap at least a portion of the first extension face EF1.

FIG. 13 is a perspective view schematically illustrating a display panel 200 attached to a guide film 300 aligned over a pad PAD.

Referring to FIG. 13, the manufacturing method for the display device DD (see FIG. 1) may include respectively fastening grip portions GR to free ends of the extension faces EF.

In an embodiment, the grip portions GR may include a first grip portion GR1, a second grip portion GR2, a third grip portion GR3, and a fourth grip portion GR4.

The first grip portion GR1 may be engaged at the free end of the first extension face EF1. In an embodiment, the first grip portion GR1 may be engaged at the free end of the first-2 portion P1-2. The second grip portion GR2 may be engaged at the free end of the second extension face EF2. A third grip portion GR3 may be engaged at the free end of the third extension face EF3. A fourth grip portion GR4 may be engaged at the free end of the fourth extension face EF4. Each of the first grip portion GR1, the second grip portion GR2, the third grip portion GR3, and the fourth grip portion GR4 may be spaced apart from the display panel 200 attached to the supporting surface SF (see FIG. 5).

Each of the first grip portion GR1, second grip portion GR2, third grip portion GR3, and fourth grip portion GR4 may be movable in various directions.

For example, the first grip portion GR1 may move in the first direction DR1, such that the first extension face EF1 may be tensioned in the first direction DR1 by the first grip portion GR1.

The second grip portion GR2 may move in the direction opposite to the first direction DR1, such that the second extension face EF2 may be tensioned in the direction opposite to the first direction DR1 by the second grip portion GR2.

The third grip portion GR3 may move in the second direction DR2, such that the third extension face EF3 may be tensioned in the second direction DR2 by the third grip portion GR3.

The fourth grip portion GR4 may move in the direction opposite to the second direction DR2, such that the fourth extension face EF4 may be tensioned in the direction opposite to the second direction DR2 by the fourth grip portion GR4.

In this case, the guide film 300 and the display panel 200 attached thereto may be unfolded to be substantially parallel to a plane defined by the first direction DR1 and the second direction DR2.

In an embodiment, the manufacturing method for the display device DD (see FIG. 1) may include aligning the display panel 200 attached to the guide film 300 on the pad PAD by moving the grip portions GR.

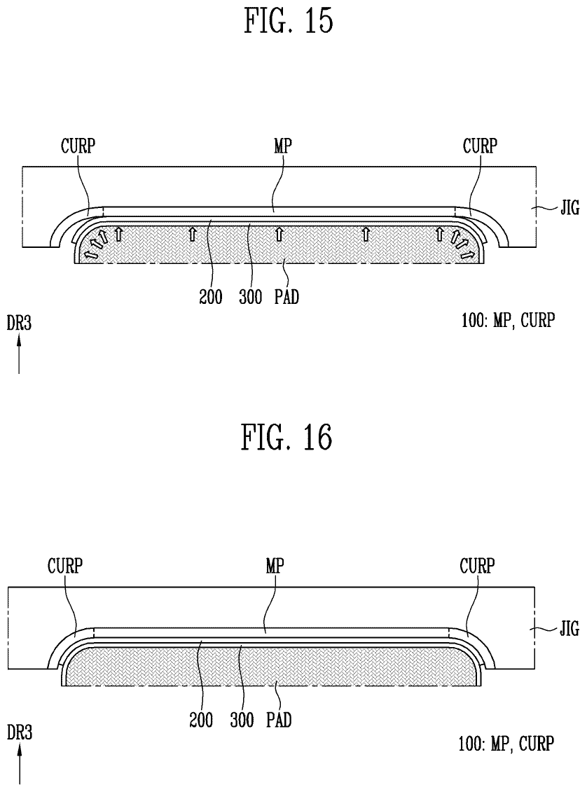

An upper surface of the pad PAD may include a curved surface that corresponds substantially to the curved surface of the window 100 (see FIG. 2). The pad PAD may be inflated by a pressure providing means within the pad PAD. In this case, the pad PAD may be shaped to include the curved surface substantially corresponding to the curved surface of the window 100 (see FIG. 2). This will be discussed further with reference to FIGS. 15 and 16.

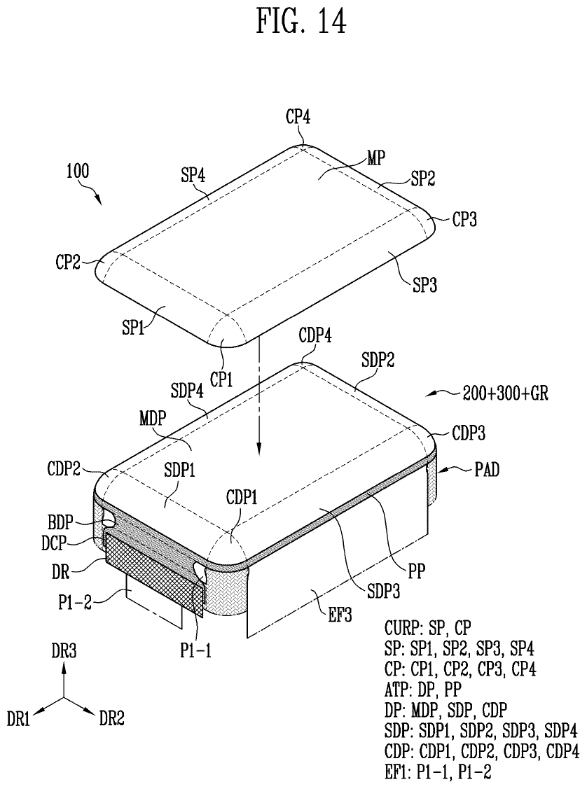

FIG. 14 is a perspective view schematically illustrating a state in which the shape of the display panel 200 has been deformed to correspond to the shape of the pad PAD by applying tension to the guide film 300.

Referring to FIG. 14, the manufacturing method for the display device DD (see FIG. 1) may include deforming the shape of the display panel 200 by applying tension to the guide film 300 while the display panel 200 is attached to the guide film 300.

In an embodiment, this step may include applying tension to each of the first extension face EF1, the second extension face EF2 (see FIG. 13), the third extension face EF3, and the fourth extension face EF4 (see FIG. 13).

For example, in addition to the tension in the first direction DR1, tension may be applied to the first extension face EF1 in the direction opposite to the third direction DR3. This may be accomplished by moving the first grip portion GR1 (see FIG. 13) in the direction opposite to the third direction DR3, but the present disclosure is not limited thereto.

In addition to the tension in the direction opposite to the first direction DR1, tension may be applied to the second extension face EF2 (see FIG. 13) in the direction opposite to the third direction DR3.

In addition to the tension in the second direction DR2, tension may be applied to the third extension face EF3 in the direction opposite to the third direction DR3.

In addition to the tension in the direction opposite to the second direction DR2, tension may be applied to the fourth extension face EF4 in the direction opposite to the third direction DR3.

In this step, the guide film 300 and the display panel 200 attached thereto may be deformed into a shape corresponding to the curved surface of the upper surface of the pad PAD.

In this step, the attachment portion ATP may be attached to the supporting face SF. That is, the attachment portion ATP may remain attached to the supporting face SF. In this case, in an embodiment, the attachment portion ATP may be spaced apart from the extension faces EF.

In an embodiment, the manufacturing method for the display device DD (see FIG. 1) may include aligning the window 100 over the display panel 200 that is shaped to correspond to a curved surface of the upper surface of the pad PAD. In this step, the window 100 may be coupled to a jig (see FIG. 15).

FIGS. 15 and 16 are cross-sectional views to illustrate how the PAD may be used to deform the shape of the display panel 200 to correspond to the shape of the window 100.

Referring to FIGS. 15 and 16, the manufacturing method for the display device DD (see FIG. 1) may include moving the jig JIG in the direction opposite the third direction DR3 to bring the window 100 and the display panel 200 into contact with each other.

In an embodiment, an adhesive layer may be provided between the window 100 and the display panel 200. Accordingly, when the window 100 and the display panel 200 are in contact with each other, the display panel 200 may be attached to the window 100.

In this step, the main display portion MDP of the display panel 200 (see FIG. 2) may contact the main portion MP of the window 100. In an embodiment, in this step, at least a portion of the curved portion CURP of the window 100 may be spaced apart from each of the side display portion SDP (see FIG. 2) and the corner display portion CDP (see FIG. 2) of the display panel 200.

Then, the manufacturing method for the display device DD (see FIG. 1) may include deforming the shape of the pad PAD to match the shape of the display panel 200 with the shape of the window 100.

In this step, the pad PAD may be inflated by a pressure providing means within the pad PAD. Accordingly, the shape of the display panel 200 may be deformed to match the shape of the window 100. For example, the shape of each of the side display portion SDP (see FIG. 2) and the corner display portion CDP (see FIG. 2) of the display panel 200 may be deformed to match the shape of the curved portion CURP of the window 100.

As such, the manufacturing method for the display device DD (see FIG. 1) may include attaching the window 100 to the display panel 200 whose shape has been deformed by the steps described with reference to FIG. 14.

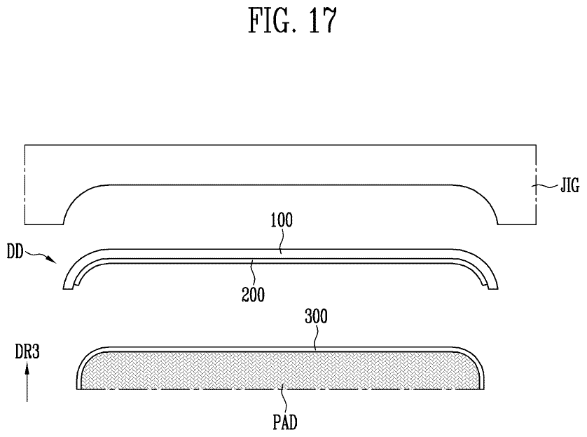

FIG. 17 is a cross-sectional view to illustrate a method of removing the jig JIG, the guide film 300, and the pad PAD.

Referring to FIG. 17, the manufacturing method for the display device DD may include removing the jig JIG, the guide film 300, and the pad PAD. Accordingly, the display device DD, which includes the window 100 including the curved surface and the display panel 200 attached below the window 100 and having a shape partially deformed to correspond to the curved surface of the window 100, may be formed.

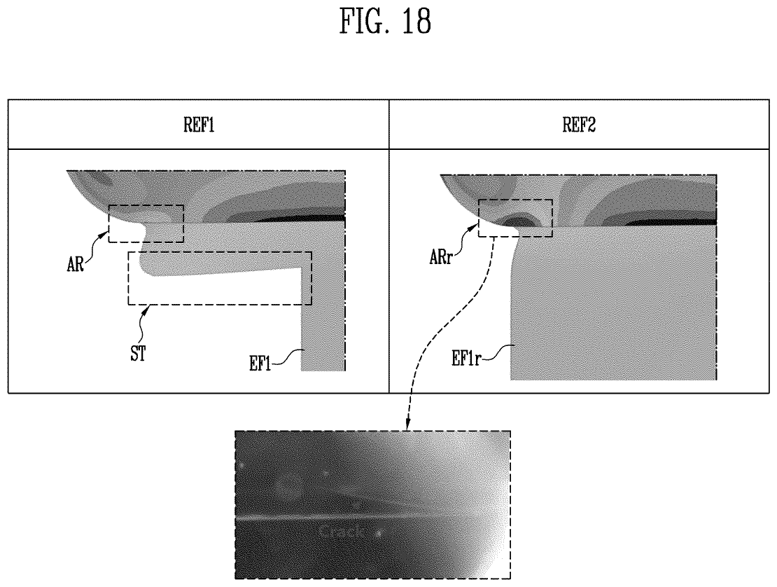

FIG. 18 is a drawing to illustrate the effect of a manufacturing method using the guide film of FIG. 5.

Referring to FIG. 18, a first reference example REF1 illustrates a stress distribution in some areas of the display panel 200 (see FIG. 2) as seen during a manufacturing process using the guide film 300 (see FIG. 5) of the present disclosure.

The second reference example REF2 illustrates a stress distribution in some areas of the display panel 200 (see FIG. 2) as seen during a manufacturing process using a guide film including a first extension face EF1 in which a step shape ST is not defined, as compared to the first reference example REF1 related to a first extension face EF1 in which the step shape ST is defined.

Here, the manufacturing process in each of the first reference example REF1 and the second reference example REF2 may be described as shown in FIG. 14.

In FIG. 18, for simplicity, only the stress distribution in some areas of the attachment portion ATP (see FIG. 2) of the display panel 200 (see FIG. 2) is shown, omitting the bending portion BDP (see FIG. 2), the connection portion DCP (see FIG. 2), and the driving member DR (see FIG. 2).

Referring to the first reference example REF1, it may be seen that stress concentration in an adjacent area AR of attachment portion ATP (see FIG. 2) adjacent to the bending portion BDP (see FIG. 2) is effectively prevented as the step shape ST absorbs stress. The adjacent area AR may be an area corresponding to the first adjacent area AR1 (see FIG. 5).

On the other hand, referring to the second reference example REF2, in the case where the step shape ST is not defined, a problem may appear in which stresses are excessively concentrated in an adjacent area ARr of the attachment portion ATP (see FIG. 2) adjacent to the bending portion BDP (see FIG. 2), causing cracks in the attachment portion ATP (see FIG. 2).

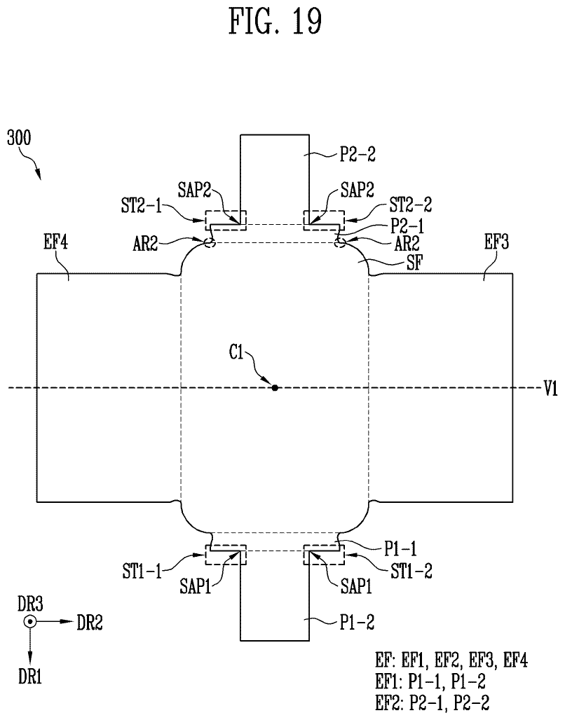

FIG. 19 is a plan view to illustrate a variant of the guide film of FIG. 5. Description that is redundant of that described with reference to FIGS. 1 to 11 may be omitted.

Referring to FIG. 19, the shape of the first extension face EF1 and the shape of the second extension face EF2 may be symmetrical to each other with respect to a virtual line V1. For example, the virtual line V1 may be a line extending in the first direction DR1 through a center C1 of the supporting face SF. In this case, the tension applied to the first extension face EF1 and the tension applied to the second extension face EF2 may be balanced, and stresses may be prevented from being concentrated in a particular area of the supporting face SF (or the attachment portion ATP attached to the supporting face SF (see FIG. 2)).

The second extension face EF2 may include a second-1 portion P2-1 and a second-2 portion P2-2. The second-1 portion P2-1 may be a portion adjacent to the supporting face SF in a direction opposite to the first direction DR1. The second-1 portion P2-1 may extend from the supporting face SF in the direction opposite to the first direction DR1. The second-2 portion P2-2 may extend from the second-1 portion P2-1 in the direction opposite to the first direction DR1. The second-2 portion P2-2 may be spaced apart from the supporting face SF, and the second-1 portion P2-1 may be disposed between the second-2 portion P2-2 and the supporting face SF.

In an embodiment, in an area adjacent to an area where the second-1 portion P2-1 and the second-2 portion P2-2 are in contact, the second extension face EF2 may define a second-1 step shape ST2-1 and a second-2 step shape ST2-2 that are embedded in a direction facing each other. Each of the second-1 step shape ST2-1 and the second-2 step shape ST2-2 may be a step shape formed between the second-1 portion P2-1 and the second-2 portion P2-2.

The second-1 step shape ST2-1 and the second-2 step shape ST2-2 may serve to prevent stresses caused by tension applied to the second extension face EF2 from being concentrated in a second adjacent area AR2 adjacent to the portion of the supporting face SF contacting the second extension face EF2. Accordingly, when the attachment portion ATP (see FIG. 2) is attached to the supporting face SF, the second-1 step shape ST2-1 and the second-2 step shape ST2-2 may effectively prevent stress from being concentrated in a portion of the attachment portion ATP (see FIG. 2) corresponding to the second adjacent area AR2 as the second-1 step shape ST2-1 and the second-2 step shape ST2-2 absorb the stress caused by the tension.

In an embodiment, each of the second-1 step shape ST2-1 and the second-2 step shape ST2-2 may include a second stress absorption point SAP2, which is a point where an edge of the second-1 portion P2-1 and an edge of the second-2 portion P2-2 meet to form an angle of less than or equal to a reference angle. The reference angle may be, for example, about 150 degrees or less, about 140 degrees or less, about 130 degrees or less, about 120 degrees or less, about 110 degrees or less, about 100 degrees or less, about 90 degrees or less, about 80 degrees or less, about 70 degrees or less, or about 60 degrees or less. When the reference angle is set as described above, stresses may be effectively concentrated at the second stress absorption point SAP2.

The second-1 portion P2-1 and the second-2 portion P2-2 may have various shapes capable of defining the second-1 step shape ST2-1 and the second-2 step shape ST2-2. For example, the description described with reference to FIGS. 8 to 10 may likewise apply.

In an embodiment, the second-1 step shape ST2-1 and the second-2 step shape ST2-2 may be symmetrical to each other. In this case, the stresses caused by the tension applied to the second extension face EF2 may be prevented from being biased in the second direction DR2 or in a direction opposite to the second direction DR2. That is, the stresses caused by the tension may be evenly distributed and the maximum intensity of these stresses may be reduced.

In an embodiment, each of the second-1 step shape ST2-1 and the second-2 step shape ST2-2 may be spaced apart from the supporting face SF. Accordingly, stresses absorbed by the second-1 step shape ST2-1 and the second-2 step shape ST2-2 may be prevented from being transmitted to the supporting face SF (or to the attachment portion ATP attached to the supporting face SF (see FIG. 2)).

In an embodiment, a shape of the guide film 300 shown in FIG. 19 may be symmetrical with respect to the first direction DR1 and the second direction DR2. For example, the shape of the guide film 300 shown in FIG. 19 may be symmetrical with respect to a line (e.g., line I1-I2 in FIG. 5) extending in the first direction DR1 through a center of the supporting face SF and, at the same time, symmetrical with respect to a line (e.g., line 13-14 in FIG. 5) extending in the second direction DR2 through the center of the supporting face SF. Accordingly, the tensions applied to the first extension face EF1, the second extension face EF2, the third extension face EF3, and the fourth extension face EF4 may be balanced, and stresses may be prevented from being concentrated in a particular area of the supporting face SF (or the attachment portion ATP attached to the supporting face SF (see FIG. 2)).

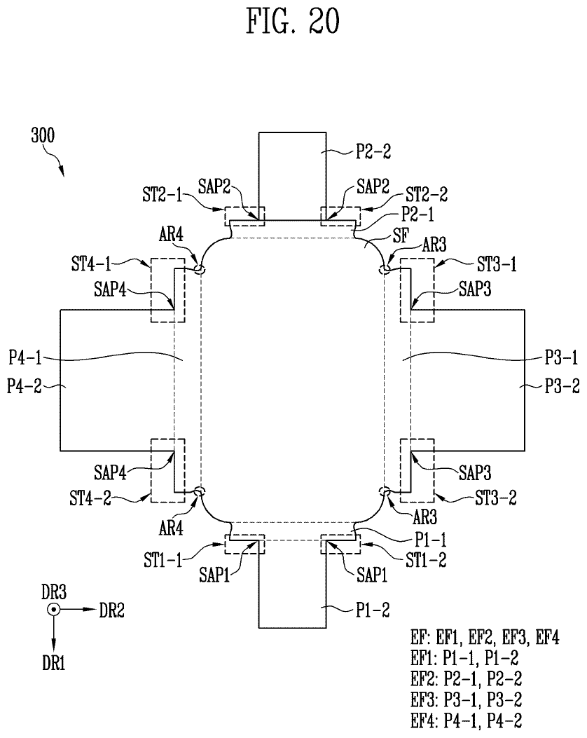

FIG. 20 is a plan view to illustrate another variant of the guide film of FIG. 5. Description that is redundant of that described with reference to FIGS. 1 to 11 and FIG. 19 may be omitted.

Referring to FIG. 20, a step shape may also be defined on the third extension face EF3 and the fourth extension face EF4. In this case, a shape of the third extension face EF3 and a shape of the fourth extension face EF4 may be symmetrical to each other.

The third extension face EF3 may include a third-1 portion P3-1 and a third-2 portion P3-2. The third-1 portion P3-1 may be adjacent to the supporting face SF in the second direction DR2. The third-1 portion P3-1 may extend from the supporting face SF in the second direction DR2. The third-2 portion P3-2 may extend in the second direction DR2 from the third-1 portion P3-1. The third-2 portion P3-2 may be spaced apart from the supporting face SF, and the third-1 portion P3-1 may be disposed between the third-2 portion P3-2 and the supporting face SF.

In an embodiment, in an area adjacent to an area where the third-1 portion P3-1 and the third-2 portion P3-2 are in contact, the third extension face EF3 may define a third-1 step shape ST3-1 and a third-2 step shape ST3-2 that are embedded in a direction facing each other. Each of the third-1 step shape ST3-1 and the third-2 step shape ST3-2 may be a step shape formed between the third-1 portion P3-1 and the third-2 portion P3-2.

In an embodiment, each of the third-1 step shape ST3-1 and the third-2 step shape ST3-2 may include a third stress absorption point SAP3, which is a point where an edge of the third-1 portion P3-1 and an edge of the third-2 portion P3-2 meet to form an angle below a reference angle. The reference angle may be, for example, about 150 degrees or less, about 140 degrees or less, about 130 degrees or less, about 120 degrees or less, about 110 degrees or less, about 100 degrees or less, about 90 degrees or less, about 80 degrees or less, about 70 degrees or less, or about 60 degrees or less.

The third-1 portion P3-1 and the third-2 portion P3-2 may have various shapes capable of defining the third-1 step shape ST3-1 and the third-2 step shape ST3-2. For example, the description described with reference to FIGS. 8 to 10 may likewise apply.

In an embodiment, the third-1 step shape ST3-1 and the third-2 step shape ST3-2 may be symmetrical to each other. In this case, the stresses caused by the tension applied to the third extension face EF3 may be prevented from being biased in the first direction DR1 or in a direction opposite to the first direction DR1. In other words, the stresses caused by the tension may be evenly distributed and the maximum intensity of these stresses may be reduced.

In an embodiment, each of the third-1 step shape ST3-1 and the third-2 step shape ST3-2 may be spaced apart from the supporting face SF. Thus, stresses absorbed by the third-1 step shape ST3-1 and the third-2 step shape ST3-2 may be prevented from being transmitted to the supporting face SF (or to the attachment portion ATP (see FIG. 2) attached to the supporting face SF).

As the third-1 step shape ST3-1 and the third-2 step shape ST3-2 are defined on the third extension face EF3, the third-1 step shape ST3-1 and the third-2 step shape ST3-2 may serve to absorb the stress. Thus, stress concentration in a portion of the attachment portion ATP (see FIG. 2) corresponding to a third adjacent area AR3 may be effectively prevented. Here, the third adjacent area AR3 may be an area adjacent to a portion of the supporting face SF that contacts the third extension face EF3.

The fourth extension face EF4 may include a fourth-1 portion P4-1 and a fourth-2 portion P4-2. The fourth-1 portion P4-1 may be a portion adjacent to the supporting face SF in a direction opposite to the second direction DR2. The fourth-1 portion P4-1 may extend from the supporting face SF in the direction opposite to the second direction DR2. The fourth-2 portion P4-2 may extend from the fourth-1 portion P4-1 in the direction opposite to the second direction DR2. The fourth-2 portion P4-2 may be spaced apart from the supporting face SF, and the fourth-1 portion P4-1 may be disposed between the fourth-2 portion P4-2 and the supporting face SF.

In an embodiment, in an area adjacent to the area where the fourth-1 portion P4-1 and the fourth-2 portion P4-2 are in contact, the fourth extension face EF4 may define a fourth-1 step shape ST4-1 and a fourth-2 step shape ST4-2 that are embedded in a direction facing each other. Each of the fourth step shape ST4-1 and the fourth step shape ST4-2 may be a step shape formed between the fourth portion P4-1 and the fourth portion P4-2.

In an embodiment, each of the fourth-1 step shape ST4-1 and the fourth-2 step shape ST4-2 may include a fourth stress absorption point SAP4, which is a point where an edge of the fourth-1 step shape ST4-1 and an edge of the fourth-2 step shape ST4-2 meet to form an angle below a reference angle. The reference angle may be, for example, about 150 degrees or less, about 140 degrees or less, about 130 degrees or less, about 120 degrees or less, about 110 degrees or less, about 100 degrees or less, about 90 degrees or less, about 80 degrees or less, about 70 degrees or less, or about 60 degrees or less.

The fourth-1 portion P4-1 and the fourth-2 portion P4-2 may have various shapes capable of defining the fourth-1 step shape ST4-1 and the fourth-2 step shape ST4-2. For example, the description described with reference to FIGS. 8 to 10 may likewise apply.

In an embodiment, the fourth step shape ST4-1 and the fourth step shape ST4-2 may be symmetrical to each other. In this case, the stresses caused by the tension applied to the fourth extension face EF4 may be prevented from being biased in the first direction DR1 or in a direction opposite to the first direction DR1. In other words, the stresses caused by the tension may be evenly distributed and the maximum intensity of these stresses may be reduced.

In an embodiment, each of the fourth-1 step shape ST4-1 and fourth-2 step shape ST4-2 may be spaced apart from the supporting face SF. Accordingly, stresses absorbed by the fourth step shape ST4-1 and the fourth step shape ST4-2 may be prevented from being transmitted to the supporting face SF (or to the attachment portion ATP attached to the supporting face SF (see FIG. 2)).

As the fourth step shape ST4-1 and the fourth step shape ST4-2 are defined on the fourth extension face EF4, the fourth step shape ST4-1 and the fourth step shape ST4-2 may play a role in absorbing stress. Accordingly, stress may be effectively prevented from being concentrated in a portion of the attachment portion ATP (see FIG. 2) corresponding to a fourth adjacent area AR4. Here, the fourth adjacent area AR4 may be an area adjacent to a portion of the supporting face SF that contacts the fourth extension face EF4.

In an embodiment, the shape of the guide film 300 shown in FIG. 20 may be symmetrical with respect to the first direction DR1 and the second direction DR2. For example, the shape of the guide film 300 shown in FIG. 20 may be symmetrical with respect to a line (e.g., line I1-I2 in FIG. 5) extending in the first direction DR1 through the center of the supporting face SF and, at the same time, symmetrical with respect to a line (e.g., line 13-14 in FIG. 5) extending in the second direction DR2 through the center of the supporting face SF. Accordingly, the tensions applied to the first extension face EF1, the second extension face EF2, the third extension face EF3, and the fourth extension face EF4 may be balanced, and stresses may be prevented from being concentrated in a particular area of the supporting face SF (or the attachment portion ATP attached to the supporting face SF (see FIG. 2)).

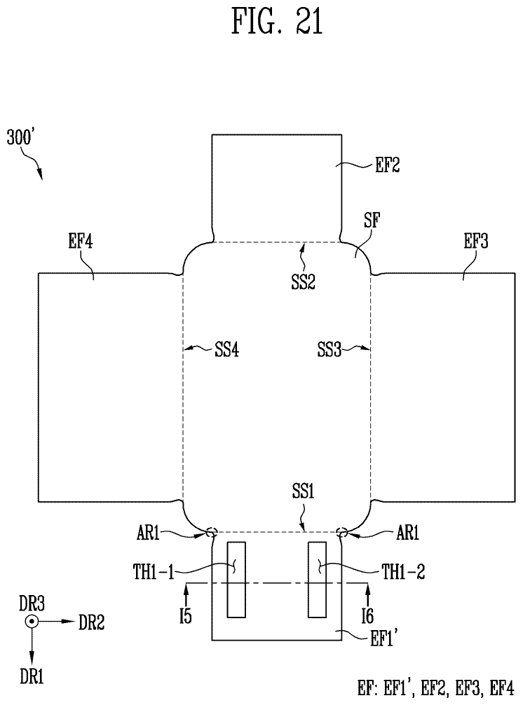

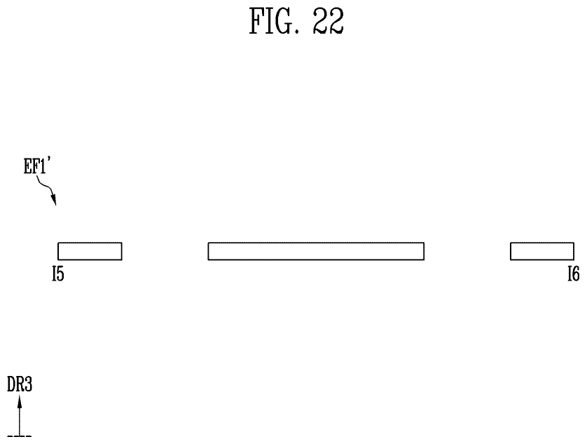

FIG. 21 is a plan view to illustrate a guide film according to another embodiment of the present disclosure. FIG. 22 is a cross-sectional view cut along line I5-I6 of FIG. 21.

Referring to FIGS. 21 and 22, the guide film 300′ may be described similarly to the guide film 300 (see FIG. 5), except that a shape of a first extension face EF1′ is different from a shape of the first extension face EF1 (see FIG. 5) of the guide film 300 (see FIG. 5). Therefore, redundant description will be omitted.

The first extension face EF1′, like the first extension face EF1 (see FIG. 5), may overlap the bending portion BDP (see FIG. 2), the connection portion DCP (see FIG. 2), and the driving member DR (see FIG. 2) when the attachment portion ATP (see FIG. 2) is attached to the supporting face SF.

In an embodiment, the first extension face EF1′ may define a first-1 through-pattern TH1-1 and a first-1 through-pattern TH1-2 that each penetrate the first extension face EF1′ in the third direction DR3. The first-1 through-pattern TH1-1 and the first-2 through-pattern TH1-2 may serve to prevent stresses caused by tension applied to the first extension face EF1′ from being concentrated in a first adjacent area AR1 adjacent to a portion of the supporting face SF contacting the first extension face EF1′. In other words, the first-1 through-pattern TH1-1 and the first-2 through-pattern TH1-2 may serve to absorb stresses caused by tension applied to the first extension face EF1′. In other words, the first-1 through-pattern TH1-1 and the first-2 through-pattern TH1-2 may perform substantially the same role as the first-1 step shape ST1-1 (see FIG. 5) and the first-2 step shape ST1-2 (see FIG. 5).

In an embodiment, each of the first-1 through-pattern TH1-1 and the first-2 through-pattern TH1-2 may be spaced apart from the supporting face SF.

The first-1 through-pattern TH1-1 and the first-2 through-pattern TH1-2 may have various shapes. In an embodiment, each of the first-1 through-pattern TH1-1 and the first-2 through-pattern TH1-2 may be rectangular in shape, with each side parallel to the first direction DR1 or the second direction DR2.

In an embodiment, a shape of the first-1 through-pattern TH1-1 and a shape of the first-2 through-pattern TH1-2 may be symmetrical to each other. In this case, the stresses caused by the tension applied to the first extension face EF1′ may be prevented from being biased in the second direction DR2 or in the direction opposite to the second direction DR2. That is, the stresses caused by the tension may be evenly distributed and the maximum intensity of these stresses may be reduced.

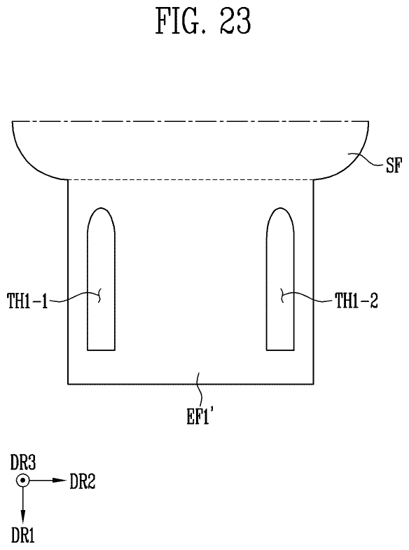

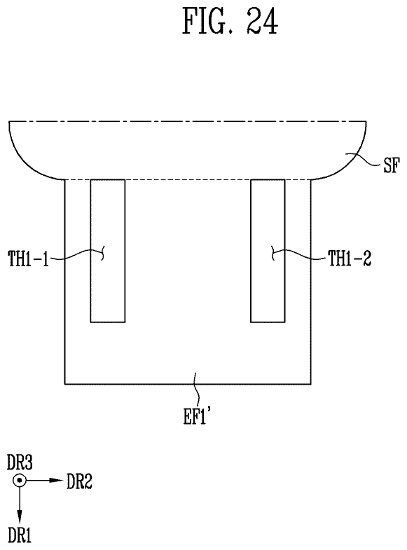

FIGS. 23 and 24 are plan views to illustrate different variations of the through-patterns of FIG. 21.

Referring to FIG. 23, each of the first-1 through-pattern TH1-1 and the first-2 through-pattern TH1-2 may have a rectangular shape with a rounded portion adjacent to the supporting face SF and may be spaced apart from the supporting face SF.

Referring to FIG. 24, each of the first-1 through-pattern TH1-1 and the first-2 through-pattern TH1-2 may have a rectangular shape, and at least a portion of each of the first-1 through-pattern TH1-1 and the first-2 through-pattern TH1-2 may contact the supporting face SF.

With respect to shapes of the first-1 through-pattern TH1-1 and the first-2 through-pattern TH1-2, the intensity of the stress concentrated in the first adjacent area AR1 (see FIG. 21) is shown in relative values (a.u.) in Table 1 below. In the Table 1 below, the second reference example REF2 (see FIG. 18) is described as previously described with reference to FIG. 18.

TABLE 1

| | | | | Second |
|---|---|---|---|---|
| | | | | reference |
| | Embodiment | Embodiment | Embodiment | example |
| | of FIG. 21 | of FIG. 23 | of FIG. 24 | REF2 |
| Stress | 0.30 | 0.38 | 0.23 | 0.45 |
| intensity | | | | |
| [a.u.] | | | | |

Referring to Table 1 above, it may be seen that, compared to the second reference example REF2, the intensity of the stress concentrated in the first adjacent area AR1 (see FIG. 21) is significantly reduced as the first-1 through-pattern TH1-1 and the first-2 through-pattern TH1-2 are defined on the first extension face EF1′. Furthermore, it may be seen that the stress intensity concentrated in the first adjacent area AR1 (see FIG. 21) is further reduced in the embodiment of FIG. 24, where at least a portion of each of the first-1 through-pattern TH1-1 and the first-1 through-pattern TH1-2 is tangent to the supporting face SF, compared to the embodiment of FIG. 21 and the embodiment of FIG. 23, where each of the first-1 through-pattern TH1-1 and the first-1 through-pattern TH1-2 is spaced apart from the supporting face SF.

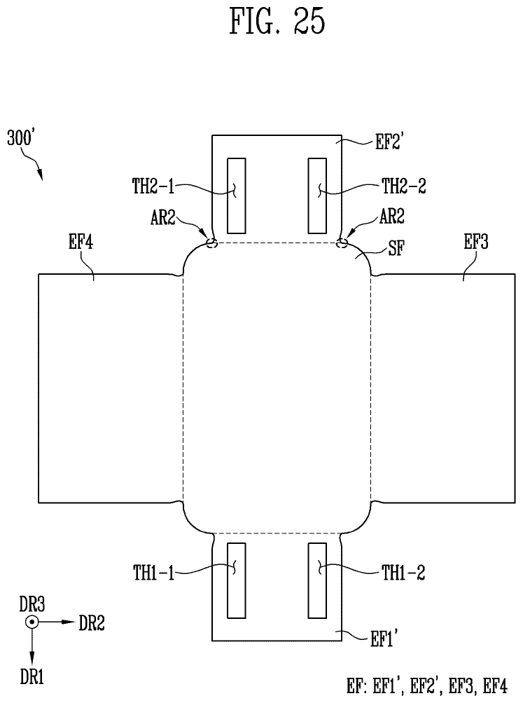

FIG. 25 is a plan view to illustrate a variant of the guide film of FIG. 21. Description that is redundant of that described with reference to FIGS. 21 to 24 may be omitted.

Referring to FIG. 25, a shape of a first extension face EF1′ and a shape of a second extension face EF2′ may be symmetrical to each other. In this case, the tension applied to the first extension face EF1′ and the tension applied to the second extension face EF2′ may be balanced, and stresses may be prevented from being concentrated in a particular area of the supporting face SF (or the attachment portion ATP attached to the supporting face SF (see FIG. 2)).

More specifically, the second extension face EF2′ may define a second-1 through-pattern TH2-1 and a second-2 through-pattern TH2-2 that each penetrate the second extension face EF2′ in the third direction DR3. The second-1 through-pattern TH2-1 and the second-2 through-pattern TH2-2 may serve to prevent stresses caused by tension applied to the second extension face EF2′ from being concentrated in a second adjacent area AR2 adjacent to the portion of the supporting face SF contacting the second extension face EF2′. In other words, the second-1 through-pattern TH2-1 and the second-2 through-pattern TH2-2 may perform substantially the same role as the second-1 step shape ST2-1 (see FIG. 19) and the second step shape ST2-2 (see FIG. 19).

The second-1 through-pattern TH2-1 and second-2 through-pattern TH2-2 may have various shapes. For example, the description described with reference to FIGS. 21, 23, and 24 may likewise apply.

In an embodiment, a shape of the second-1 through-pattern TH2-1 and a shape of the second-2 through-pattern TH2-2 may be symmetrical to each other. In this case, the stresses caused by the tension applied to the second extension face EF2′ may be prevented from being biased in the second direction DR2 or in the direction opposite to the second direction DR2. That is, the stresses caused by the tension may be evenly distributed and the maximum intensity of these stresses may be reduced.

In an embodiment, a shape of the guide film 300′ shown in FIG. 25 may be symmetrical with respect to the first direction DR1 and the second direction DR2. For example, the shape of the guide film 300 illustrated in FIG. 25 may be symmetrical with respect to a line extending in the first direction DR1 through the center of the supporting face SF and, at the same time, symmetrical with respect to a line extending in the second direction DR2 through the center of the supporting face SF.

Accordingly, the tensions applied to the first extension face EF1′, the second extension face EF2′, the third extension face EF3, and the fourth extension face EF4 may be balanced, and stresses may be prevented from being concentrated in a particular area of the supporting face SF (or the attachment portion ATP attached to the supporting face SF (see FIG. 2)).

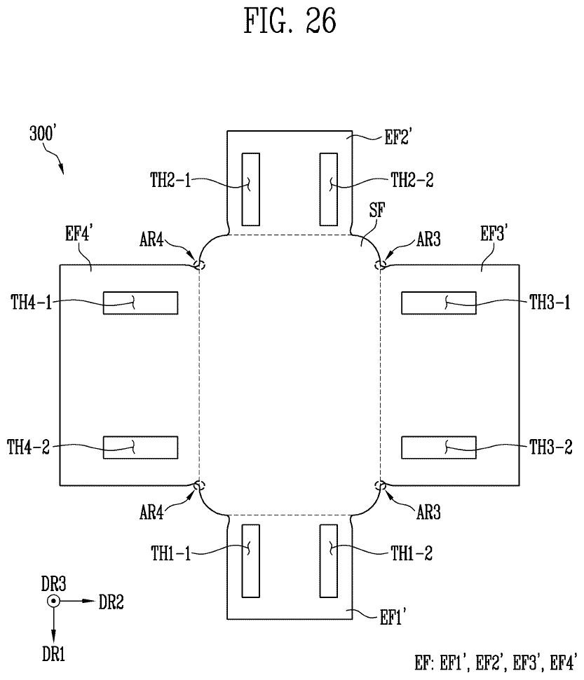

FIG. 26 is a plan view to illustrate another variant of the guide film of FIG. 21. Description that is redundant of that described with reference to FIGS. 21 to 25 may be omitted.

Referring to FIG. 25, a through-pattern may also be defined in a third extension face EF3′ and a fourth extension face EF4′. In this case, a shape of the third extension face EF3′ and a shape of the fourth extension face EF4′ may be symmetrical to each other.

The third extension face EF3′ may have a third-1 through-pattern TH3-1 and a third-2 through-pattern TH3-2 defined in the third extension face EF3′ that penetrate the third extension face EF3′ in the third direction DR3, respectively. The third-1 through-pattern TH3-1 and the third-2 through-pattern TH3-2 may serve to prevent stresses caused by applied to the tension on the third extension face EF3′ from being concentrated in a third adjacent area AR3 adjacent to a portion of the supporting face SF contacting the third extension face EF3′. In other words, the third-1 through-pattern TH3-1 and the third-2 through-pattern TH3-2 may perform substantially the same role as the third-1 step shape ST3-1 (see FIG. 20) and the third-2 step shape ST3-2 (see FIG. 20).

The third-1 through-pattern TH3-1 and third-2 through-pattern TH3-2 may have various shapes. For example, the description described with reference to FIGS. 21, 23, and 24 may likewise apply.

In an embodiment, a shape of the third-1 through-pattern TH3-1 and the shape of the third-2 through-pattern TH3-2 may be symmetrical to each other. In this case, the stresses caused by the tension applied to the third extension face EF3′ may be prevented from being biased in the first direction DR1 or in the direction opposite to the first direction DR1. That is, the stresses caused by the tension may be evenly distributed and the maximum intensity of these stresses may be reduced.

In the fourth extension face EF4′, a fourth-1 through-pattern TH4-1 and a fourth-2 through-pattern TH4-2 may be defined, which respectively penetrate the fourth extension face EF4′ in the third direction DR3. The fourth-1 through-pattern TH4-1 and the fourth-2 through-pattern TH4-2 may serve to prevent stresses caused by applied to the tension on the fourth extension face EF4′ from being concentrated in a fourth adjacent area AR4 adjacent to a portion of the supporting face SF contacting the fourth extension face EF4′. In other words, the fourth-1 through-pattern TH4-1 and the fourth-2 through-pattern TH4-2 may perform substantially the same role as the fourth-1 step shape ST4-1 (see FIG. 20) and the fourth-2 step shape ST4-2 (see FIG. 20).

The fourth-1 through-pattern TH4-1 and the fourth-2 through-pattern TH4-2 may have various shapes. For example, the description described with reference to FIGS. 21, 23, and 24 may likewise apply.

In an embodiment, a shape of the fourth-1 through-pattern TH4-1 and a shape of the fourth-2 through-pattern TH4-2 may be symmetrical to each other. In this case, the stresses caused by the tension applied to the fourth extension face EF4′ may be prevented from being biased in the first direction DR1 or in the direction opposite to the first direction DR1. In other words, the stresses caused by the tension may be evenly distributed and the maximum intensity of these stresses may be reduced.

In an embodiment, a shape of the guide film 300′ shown in FIG. 26 may be symmetrical with respect to the first direction DR1 and the second direction DR2. For example, the shape of the guide film 300′ shown in FIG. 26 may be symmetrical with respect to a line extending through the center of the supporting face SF in the first direction DR1 and, at the same time, symmetrical with respect to a line extending through the center of the supporting face SF in the second direction DR2. Accordingly, the tensions applied to the first extension face EF1′, the second extension face EF2′, the third extension face EF3′, and the fourth extension face EF4′ may be balanced, and stresses may be prevented from being concentrated in a particular area of the supporting face SF (or the attachment portion ATP attached to the supporting face SF (see FIG. 2)).

While the above embodiments have been described with reference to the above embodiments, it will be understood by those skilled in the art that various modifications and changes may be made to the present disclosure without departing from the ideas and scope of the present disclosure as set forth in the following patent claims.

What is claimed is:

1. A guide film comprising:
a supporting face; and
extension faces contacting portions of an edge of the supporting face at positions spaced apart from each other, respectively,
wherein, between two adjacent extension faces among the extension faces, the edge of the supporting face includes a curve,
wherein the extension faces includes:
a first extension face extending from the supporting face in a first direction;
a second extension face extending from the supporting face in a direction opposite to the first direction;
a third extension face extending from the supporting face in a second direction intersecting the first direction; and
a fourth extension face extending from the supporting face in a direction opposite to the second direction,
wherein the first extending face includes:
a first-1 portion extending from the supporting face in the first direction; and
a first-2 portion extending from the first-1 portion in the first direction, and
wherein, in an area adjacent to an area where the first-1 portion and the first-2 portion are in contact, the first extension face defines a first-1 step shape and a first-2 step shape recessed toward each other.

2. The guide film of claim 1, wherein each of the first-1 step shape and the first-2 step shape includes a first stress absorption point where an edge of the first-1 portion and an edge of the first-2 portion meet to form an angle of 100 degrees or less.

3. The guide film of claim 1, wherein an average width in the second direction of the first-1 portion is greater than an average width in the second direction of the first-2 portion.

4. The guide film of claim 1, wherein the first-1 step shape and the first-2 step shape are symmetrical to each other with respect to a virtual line parallel to the first direction and crossing a center of the first extending face.

5. The guide film of claim 1, wherein each of the first-1 step shape and the first-2 step shape is spaced apart from the supporting face.

6. The guide film of claim 1, wherein a shape of the first extension face and a shape of the second extension face are symmetrical to each other with respect to a virtual line parallel to the second direction and crossing a center of the supporting face.

7. The guide film of claim 1, wherein a shape of the third extension face and a shape of the fourth extension face are symmetrical to each other with respect to a virtual line parallel to the first direction and crossing a center of the supporting face.

8. The guide film of claim 1, wherein, in an area adjacent to the supporting face, an edge of each of the extension faces includes a curve.

9. The guide film of claim 1, wherein a first length of a first side where the first extension face contacts the supporting face, a second length of a second side where the second extension face contacts the supporting face, a third length of a third side where the third extension face contacts the supporting face, and a fourth length of a fourth side where the fourth extension face contacts the supporting face are defined, respectively, and
wherein each of the first length and the second length is smaller than each of the third length and the fourth length.

10. A guide film comprising:
a supporting face; and
extension faces contacting portions of an edge of the supporting face at positions spaced apart from each other, respectively,
wherein, between two adjacent extension faces among the extension faces, the edge of the supporting face includes a curve,
wherein the extension faces includes:
a first extension face extending from the supporting face in a first direction;
a second extension face extending from the supporting face in a direction opposite to the first direction;
a third extension face extending from the supporting face in a second direction intersecting the first direction; and
a fourth extension face extending from the supporting face in a direction opposite to the second direction, and
wherein the first extension face defines a first-1 through-pattern and a first-2 through-pattern therein, each penetrating the first extension face in a third direction perpendicular to both the first direction and the second direction.

11. The guide film of claim 10, wherein a shape of the first-1 through-pattern and a shape of the first-2 through-pattern are symmetrical to each other with respect to a virtual line parallel to the first direction and crossing a center of the first extending face.

12. The guide film of claim 10, wherein each of the first-1 through-pattern and the first-2 through-pattern has a rectangular shape with respective sides parallel to the first direction or the second direction.

13. The guide film of claim 12, wherein at least a portion of each of the first-1 through-pattern and the first-2 through-pattern contacts the supporting face.

14. The guide film of claim 10, wherein a shape of the first extension face and a shape of the second extension face are symmetrical to each other with respect to a virtual line parallel to the second direction and crossing a center of the supporting face.

15. The guide film of claim 10, wherein a shape of the third extension face and a shape of the fourth extension face are symmetrical to each other with respect to a virtual line parallel to the first direction and crossing a center of the supporting face.

16. The guide film of claim 10, wherein a first length of a first side where the first extension face contacts the supporting face, a second length of a second side where the second extension face contacts the supporting face, a third length of a third side where the third extension face contacts the supporting face, and a fourth length of a fourth side where the fourth extension face contacts the supporting face are defined, respectively, and
wherein each of the first length and the second length is smaller than each of the third length and the fourth length.

17. A method for manufacturing an electronic device, the electronic device including a window including a curved surface; and a display panel attached below the window and having a shape partially deformed to correspond to the curved surface of the window, the method including:
deforming a shape of the display panel by applying tension to a guide film while the display panel is attached to the guide film,
wherein the guide film includes a supporting face to which the display panel is attached; and extension faces contacting portions of an edge of the supporting face at positions spaced apart from each other, respectively,
wherein, between two adjacent extension faces among the extension faces, the edge of the supporting face includes a curve,
wherein the extension faces includes:
a first extension face extending from the supporting face in a first direction;
a second extension face extending from the supporting face in a direction opposite to the first direction;
a third extension face extending from the supporting face in a second direction intersecting the first direction; and
a fourth extension face extending from the supporting face in a direction opposite to the second direction, and
wherein the first extending face includes:
a first-1 portion extending from the supporting face in the first direction; and
a first-2 portion extending from the first-1 portion in the first direction, and
wherein, in an area adjacent to an area where the first-1 portion and the first-2 portion are in contact, the first extension face defines a first-1 step shape and a first-2 step shape recessed toward each other.

18. The method for manufacturing the electronic device of claim 17, wherein the deforming of the shape of the display panel includes applying tension to each of the first extension face, the second extension face, the third extension face, and the fourth extension face.

19. The method for manufacturing the electronic device of claim 18, further including: attaching the window to the display panel having a deformed shape.

20. The method for manufacturing the electronic device of claim 17, wherein the display panel includes an attachment portion attached to the window; and a bending portion extending from the attachment portion, and
wherein in the deforming of the shape of the display panel, the attachment portion is attached to the supporting face and is spaced apart from the extension faces, and the bending portion overlaps at least a portion of the first extending face.
